(19) United States
(12) Patent Application Publication
(10) Pub. No.: US 2003/0232281 A1
(43) Pub. Date: Dec. 18, 2003

(54) Method for making lithographic printing plate

(75) Inventors: Noriaki Watanabe, Shizuoka (JP); Tomoyoshi Mitsumoto, Shizuoka (JP); Kazuo Maemoto, Shizuoka (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/368,373

(22) Filed: Feb. 20, 2003

(30) Foreign Application Priority Data
Feb. 20, 2002 (JP) P.2002-043566

(51) Int. Cl. G03F 7/26

(52) U.S. Cl. 430/302

(57) ABSTRACT

A method for making a lithographic printing plate comprising development processing a laser beam exposed positive-working lithographic printing plate precursor comprising an aluminum support having thereon a heat-sensitive layer which contains a water-insoluble and alkali-soluble resin and an infrared absorbing agent and increases solubility in an alkaline aqueous solution upon being heated, using an automatic developing processor having a developing tank and a finishing gum-coating tank, wherein pH of a fresh solution for the finishing gum is adjusted to 4.5 or more.

### FIELD OF THE INVENTION

The present invention relates to a method for making a lithographic printing plate and, particularly, to a method for making a lithographic printing plate from an infrared laser positive-working lithographic printing plate precursor for so-called direct plate making capable of making a printing plate using digital signals from a computer or the like.

### BACKGROUND OF THE INVENTION

Remarkable progress of laser has been made in recent years. Particularly, high-power and small-sized solid state lasers and semiconductor lasers having a light-emitting region in the near-infrared to the infrared region have become easily available. These lasers are extremely useful as a light source for exposure upon making a printing plate directly from digital data given from a computer or the like.

The infrared laser positive-working lithographic printing plate precursor (material) contains an alkaline aqueous solution-soluble binder resin and an IR dye or the like capable of absorbing light to generate heat as necessary components, wherein the IR dye or the like functions in unexposed areas (image areas) as a dissolution-preventing agent which substantially reduces solubility of the binder resin through mutual action with the binder resin.

When such IR laser positive-working lithographic printing plate material is imagewise exposed with laser light, the mutual action between the IR dye or the like and the binder resin is reduced in exposed areas (non-image areas) due to the generated heat, thus the binder resin becoming soluble in an alkaline developing solution.

In such IR laser positive-working lithographic printing plate materials, however, difference between dissolution resistance of the unexposed areas (image areas) against a developing solution and dissolution property of the exposed areas (non-image areas), i.e., discrimination, under various conditions is insufficient.

Usually, a printing plate material having been subjected to the development processing is subjected to finishing gum processing for protecting the plate surface after being subjected to rinsing processing with a washing liquid such as water to wash away the developing solution on the surface. The finishing gum processing includes a processing of applying a hydrophilic high-molecular compound to the surface of a printing plate material for the purpose of preventing the non-image areas from contamination due to organic substances in the air (gumming treatment) and a processing of neutralizing with an acid the surface of the printing plate material having been made alkaline with the developing solution. Thus, a processing solution to be used for such finishing gum processing necessarily contains a hydrophilic resin and an acid.

In the plate-making works of making a lithographic printing plate from a lithographic printing plate material comprising the development processing, the rinsing processing and the finishing gum processing as described above, automatic developing processors for PS plates have widely been employed in recent years because of rationalization and standardization of the works. The automatic developing processors ordinarily comprise a developing zone and zones for conducting respective post-processings, and also a device for conveying a PS plate, tanks for respective processing solutions and a spraying device. There have been known a method wherein each processing solution is pumped up and sprayed through a spray nozzle over an exposed PS plate while horizontally conveying it to conduct development processing and post-processings and a method wherein a PS plate is dipped into and conveyed through a processing tank filled with a processing solution by means of guide rolls provided in the solution to thereby conduct development.

The infrared laser positive-working lithographic printing plate material has involved the problems that, since it shows an insufficient discrimination as described hereinbefore, (1) non-image areas of the printing plate is not fully developed even in the finishing gum processing zone of an automatic developing processor, and a binder component deposits in the acidic finishing gum processing solution to form scum on the non-image areas of the printing plate, and (2) the binder component having once been developed and removed in the film form re-adheres on the image areas to partly deteriorate ink-receptive property.

### SUMMARY OF THE INVENTION

An object of the invention is to solve the above-described problems in the conventional technology.

Another object of the invention is to provide a method for making a lithographic printing plate which can depress the formation of scum on the surface of non-image areas of a printing plate after the development processing and which can improve ink-receptive property of image areas when an infrared laser positive-working lithographic printing plate material is used.

As a result of intensive investigations, the inventors have found that the above-described objects can be attained by controlling pH of a fresh solution to be charged into a finishing gum processing zone of an automatic developing processor.

Specifically, the objects of the invention is attained by the following constitutions:

(1) A method for making a lithographic printing plate comprising development processing a laser beam exposed positive-working lithographic printing plate precursor comprising an aluminum support having thereon a heat-sensitive layer which contains a water-insoluble and alkali-soluble resin and an infrared absorbing agent and increases solubility in an alkaline aqueous solution upon being heated, using an automatic developing processor having a developing tank and a finishing gum-coating tank, wherein pH of a fresh solution for the finishing gum is adjusted to 4.5 or more.

(2) The method for making a lithographic printing plate as described in item (1), wherein the alkali-soluble resin comprises a copolymer containing a monomer having a sulfonamido group wherein at least one hydrogen atom is bonded to the nitrogen atom in an amount of 10 mol % or more as a copolymerizable component and an alkali-soluble resin having a phenolic hydroxyl group.

### DETAILED DESCRIPTION OF THE INVENTION

The invention is described in detail below.

The finishing gum processing solution for use in the invention is not particularly limited as long as pH of a fresh solution thereof is 4.5 or more. The pH of the fresh solution is preferably in a range of 4.5 to 7.0 and more preferably in a range of 4.5 to 5.0.

The method for adjusting the pH within the above range is not particularly limited, and an ordinary method, for example, a method of adding an alkali or a method of removing an acidic component can be used.

In case when the pH is less than 4.5, sufficient effects cannot be obtained. On the other hand, when the pH is higher than 7.0, the pH would become too high later in the running of processing, resulting in increased staining and reduction of film thickness in the image areas in some cases. Although the reason for the excessive increase of pH and the increased staining later in the running of processing described above is not clear, but it is presumed that COOH of the water-soluble resin contained in the finishing gum processing solution dissociates and forms a salt, thereby decreasing adsorbability of the water-soluble resin on the surface of printing plate.

The finishing gum processing solution for use in the invention comprises a hydrophilic high-molecular compound.

The hydrophilic high-molecular compound contained in the finishing gum processing solution is not particularly limited, and includes gum arabic or a starch derivative.

Regarding the hydrophilic high-molecular compound and other components of the finishing gum processing solution, the disclosure in JP-A-2001-381419 (the term “JP-A” as used herein means an “unexamined published Japanese patent application”) can be referred to and is incorporated herein by reference.

Also, the automatic developing processor for use in the method of the invention is not particularly limited as long as it has a developing tank and a finishing gum coating tank.

Now, the positive-working lithographic printing plate precursor for use in the method of the invention is described in detail below.

The positive-working lithographic printing plate precursor for use in the method of the invention comprises an aluminum support having thereon a heat-sensitive layer which contains a water-insoluble and alkali-soluble resin and an infrared absorbing dye and increases solubility in an alkaline aqueous solution upon being heated.

As the water-insoluble and alkali-soluble resin (hereinafter also referred to as “alkali-soluble resin”) contained in the heat-sensitive layer of the positive-working lithographic printing plate precursor for use in the method of the invention, there are illustrated, for example, phenol-formaldehyde resin, cresol-formaldehyde resin, phenol-cresol-formaldehyde co-condensation resin, phenol-modified xylene resin, polyhydroxystyrene, polyhalogenated hydroxystyrene, copolymer of N-(4-hydroxyphenyl)methacrylamide, copolymer of 4-hydroxyphenyl (meth)acrylate and, further, sulfonylimide-based polymers described in JP-A-7-28244 and carboxyl group-containing polymers described in JP-A-7-36184. Further, various alkali-soluble high-molecular compounds such as acrylic resins having phenolic hydroxyl groups as disclosed in JP-A-51-34711 and acrylic resins having sulfonamido groups described in JP-A-2-866, and urethane-based resin may also be used.

The alkali-soluble high-molecular compound preferably has a weight average molecular weight of 500 to 20,000 and a number average molecular weight of 200 to 10,000.

Such alkali-soluble high-molecular compounds may be used alone or in combination of two or more thereof. The addition amount of the alkali-soluble high-molecular compound is ordinarily 80% by weight or less based on the total solid content of the heat-sensitive layer.

Further, as is described in U.S. Pat. No. 4,123,279, it is preferred in view of improving oil-sensitization property of image to use a condensate between a phenol having an alkyl group containing 3 to 8 carbon atoms as a substituent and formaldehyde, such as tert-butylphenol-formaldehyde resin or octylphenol-formaldehyde resin, in combination with the alkali-soluble high-molecular compound. Such alkali-soluble resin is used usually in an addition amount of 90% by weight or less based on the total solid content of the heat-sensitive layer.

The alkali-soluble resin includes, particularly preferably, high-molecular compounds having one of functional groups of (a-1) phenolic hydroxyl group, (a-2) sulfonamido group and (a-3) active imido group, and there may be illustrated, for example, the following.

As the high-molecular compound having (a-1) phenolic hydroxyl group, a high-molecular compound having a phenolic hydroxyl group in the side chain thereof may be used. The high-molecular compound having a phenolic hydroxyl group in its side chain includes high-molecular compounds obtained by homopolymerization of a polymerizable monomer composed of a low-molecular compound having at least one phenolic hydroxyl group and at least one polymerizable unsaturated bond, or copolymerization of the above polymerizable monomer with other polymerizable monomer.

Examples of the polymerizable monomer having a phenolic hydroxyl group include acrylamide, methacrylamide, acrylate, methacrylate or hydroxystyrene each having a phenolic hydroxyl group. Specifically, for example, N-(2-hydroxyphenyl)acrylamide, N-(3-hydroxyphenyl)acrylamide, N-(4-hydroxyphenyl)acrylamide, N-(2-hydroxyphenyl)methacrylamide, N-(3-hydroxyphenyl)methacrylamide, N-(4-hydroxyphenyl)methacrylamide, o-hydroxyphenyl acrylate, m-hydroxyphenyl acrylate, p-hydroxyphenyl acrylate, o-hydroxyphenyl methacrylate, m-hydroxyphenyl methacrylate, p-hydroxyphenyl methacrylate, o-hydroxystyrene, m-hydroxystyrene, p-hydroxystyrene, 2-(2-hydroxyphenyl)ethyl acrylate, 2-(3-hydroxyphenyl)ethyl acrylate, 2-(4-hydroxyphenyl)ethyl acrylate, 2-(2-hydroxyphenyl)ethyl methacrylate, 2-(3-hydroxyphenyl)ethyl methacrylate, 2- (4-hydroxyphenyl)ethyl methacrylate may preferably be used.

Such resins having a phenolic hydroxyl group may be used alone or in combination of two or more thereof.

The high-molecular compound having (a-2) sulfonamido group includes high-molecular compounds obtained by homopolymerization of a polymerizable monomer having a sulfonamido group, or copolymerization of the above polymerizable monomer with other polymerizable monomer. Examples of the polymerizable monomer having a sulfonamido group include a polymerizable monomer having at least one sulfonamido group, —NH—SO₂—, wherein at least one hydrogen atom is bonded to the nitrogen atom and at least one polymerizable unsaturated bond. Among them, low-molecular compounds having an acryloyl group, an allyl group or a vinyloxy group and a substituted or unsubstituted aminosulfonyl group or a substituted sulfonylimino group are preferred.

As such compounds, there are illustrated, for example, compounds which are represented by the following formulae (a) to (e). However, the invention should not be limited to these compounds.

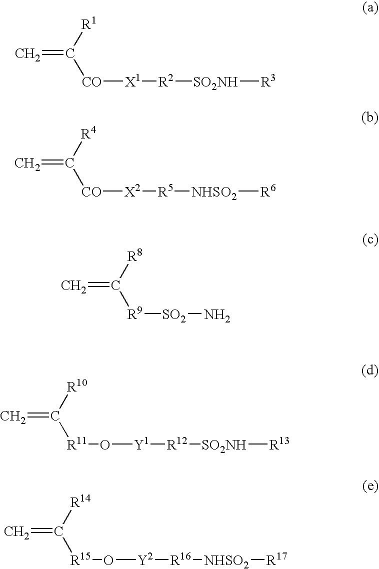

In the above formulae, X¹ and X² each independently represents an oxygen atom or NR⁷, R¹ and R⁴ each independently represents a hydrogen atom or CH₃, R², R⁵, R⁹, R¹² and R¹⁶ each independently represents an optionally substituted alkylene group containing 1 to 12 carbon atoms, a cycloalkylene group, an arylene group or an aralkylene group, R³ and R¹³ each independently represents a hydrogen atom, an optionally substituted alkyl group containing 1 to 12 carbon atoms, a cycloalkyl group, an aryl group or an aralkyl group, R⁶ and R¹⁷ each independently represents an optionally substituted alkyl group containing 1 to 12 carbon atoms, a cycloalkyl group, an aryl group or an aralkyl group, R⁸, R¹⁰ and R¹⁴each represents a hydrogen atom or CH₃, R¹¹ and R¹⁵ each independently represents a single bond or an optionally substituted alkylene group containing 1 to 12 carbon atoms, a cycloalkylene group, an arylene group or an aralkylene group, Y¹ and Y² each independently represents a single bond or CO.

Among them, for example, m-aminosulfonylphenyl methacrylate, N-(p-aminosulfonylphenyl)methacrylamide and N-(p-aminosulfonylphenyl)acrylamide are preferably used.

The high-molecular compound having (a-3) active imido group is a compound having the active imido group represented by the following formula in its molecule. The high-molecular compound includes high-molecular compounds obtained by homopolymerization of a polymerizable monomer composed of a low-molecular compound having at least one active imino group represented by the following formula and at least one polymerizable unsaturated bond, or copolymerization of the above polymerizable monomer with other polymerizable monomer.

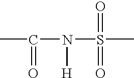

As such compound, for example, N-(p-toluenesulfonyl)methacrylamide or N-(p-toluenesulfonyl)acrylamide is preferably used.

Further, as other alkali-soluble resins, there may be used a high-molecular compound obtained by polymerizing two or more of the aforesaid polymerizable monomers having a phenolic hydroxyl group, polymerizable monomers having a sulfonamido group and polymerizable monomers having an active imido group, or a high-molecular compound obtained by copolymerizing these two or more polymerizable monomers with other polymerizable monomer.

In the case of coolymerizing the polymerizable monomer having a phenolic hydroxyl group with the polymerizable monomer having a sulfonamido group and/or the polymerizable monomer having an active imido group, the ratio of the former to the latter by weight is in a range of preferably 50:50 to 5:95, more preferably 40:60 to 10:90.

In the case where the alkali-soluble resin is a copolymer between the aforementioned polymerizable monomer having a phenolic hydroxyl group, the aforementioned polymerizable monomer having a sulfonamido group or the aforesaid polymerizable monomer having an active imido group and other polymerizable monomer, the content of the monomer capable of imparting alkali solubility is preferably 10 mol % or more, more preferably 20 mol % or more. In case when the content of the monomer is less than 10 mol %, insufficient alkali solubility is liable to result, and the effect of improving development latitude may not be sufficiently achieved.

As the monomer component copolymerized with the polymerizable monomer having a phenolic hydroxyl group, the polymerizable monomer having a sulfonamido group or the polymerizable monomer having an active imido group, monomers illustrated in the following (1) to (12) may be used. However, the monomer should not be limited thereto.

(1) acrylates and methacrylates having an aliphatic hydroxyl group such as 2-hydroxyethyl acrylate and 2-hydroxyethyl methacrylate;

(2) alkyl acrylates such as methyl acrylate, ethyl acrylate, propyl acrylate, butyl acrylate, amyl acrylate, hexyl acrylate, octyl acrylate, benzyl acrylate, 2-chloroethyl acrylate, glycidyl acrylate and N-dimethylaminoethyl acrylate;

(3) alkyl methacrylates such as methyl methacrylate, ethyl methacrylate, propyl methacrylate, butyl methacrylate, amyl methacrylate, hexyl methacrylate, cyclohexyl methacrylate, benzyl methacrylate, 2-chloroethyl methacrylate, glycidyl methacrylate and N-dimethylaminoethyl methacrylate;

(4) acrylamides or methacrylamides such as acrylamide, methacrylamide, N-methylolacrylamide, N-ethylacrylamide, N-hexylmethacrylamide, N-cyclohexylacrylamide, N-hydroxyethylacrylamide, N-phenylacrylamide, N-nitrophenylacrylamide and N-ethyl-N-phenylacrylamide;

(5) vinyl ethers such as ethyl vinyl ether, 2-chloroethyl vinyl ether, hydroxyethyl vinyl ether, propyl vinyl ether, butyl vinyl ether, octyl vinyl ether and phenyl vinyl ether;

(6) vinyl esters such as vinyl acetate, vinyl chloroacetate, vinyl butyrate and vinyl benzoate;

(7) styrenes such as styrene, α-methylstyrene and chloromethylstyrene;

(8) vinyl ketones such as methyl vinyl ketone, ethyl vinyl ketone, propyl vinyl ketone and phenyl vinyl ketone;

(9) olefines such as ethylene, propylene, isobutylene, butadiene and isoprene;

(10) N-vinylpyrrolidone, N-vinylcarbazole, 4-vinylpyridine, acrylonitrile, methacrylonitrile, etc.;

(11) Unsaturated imides such as maleimide, N-acryloylacrylamide, N-acetylmethacrylamide, N-propionylmethacrylamide and N-(p-chlorobenzoyl)methacrylamide; and

(12) Unsaturated carboxylic acids such as acrylic acid, methacrylic acid, maleic anhydride and itaconic acid.

In the case where the alkali-soluble resin is a homopolymer or copolymer of the polymerizable monomer having a phenolic hydroxyl group, the polymerizable monomer having a sulfonamido group or the polymerizable monomer having an active imido group, those having a weight average molecular weight of 2,000 or more and a number average molecular weight of 500 or more. More preferred polymers are those having a weight average molecular weight of 5,000 to 300,000, a number average molecular weight of 800 to 250,000, and a degree of dispersion (weight average molecular weight/number average molecular weight) of 1.1 to 10.

The infrared absorbing agent contained in the heat-sensitive layer of the positive-working lithographic printing plate precursor for use in the method of the invention is described below.

The infrared absorbing agent is not particularly limited, and any substance that absorbs an infrared light and generates heat may be used. Various pigments known as infrared absorbing pigments or infrared absorbing dyes other than those described below may be used as well as infrared absorbing dyes.

Examples of usable pigments include commercially available pigments and pigments described in Colour Index (C. I.), Saishin Ganryo Binran (Handbook of the Newest Pigments), edited by Nippon Ganryo Gijutu Kyokai (1977), Saishin Ganryo Oyou Gijutsu (Newest Application Techniques for Pigments), CMC Publishing Co., Ltd. (1986), and Insatsu Inki Gijutsu (Printing Ink Technology), CMC Publishing Co., Ltd. (1984).

Examples of pigment include black pigments, yellow pigments, orange pigments, brown pigments, red pigments, purple pigments, blue pigments, green pigments, fluorescent pigments, metal powder pigments, and polymer-bonding pigments. Specific examples of usable pigments include insoluble azo pigments, azo lake pigments, condensed azo pigments, chelate azo pigments, phthalocyanine pigments, anthraquinone pigments, perylene and perynone pigments, thioindigo pigments, quinacridone pigments, dioxazine pigments, isoindolinone pigments, quinophthalone pigments, Reichardt's dyes, azine pigments, nitroso pigments, nitro pigments, natural pigments, fluorescent pigments, inorganic pigments, and carbon black.

These pigments may be used either without any surface treatment or after undergoing a surface treatment. Examples of surface treatment methods include a method of coating pigment surfaces with a resin or wax, a method of adhering a surfactant to pigment surfaces, and a method of bonding a reactive substance (e.g., a silane coupling agent, an epoxy compound or a polyisocyanate) to pigment surfaces. The surface treatment methods are described in Kinzoku Sekken No Seishitsu To Oyou (Properties and Applications of Metal Soaps), Saiwai Shobo, Insatsu Inki Gijutsu (Printing Ink Technology), CMC Publishing Co., Ltd. (1984), and Saishin Ganryo Oyou Gijutsu (Newest Application Techniques for Pigments), CMC Publishing Co., Ltd. (1986).

The pigments have particle sizes of preferably in a range of 0.01 μm to 10 μm, more preferably 0.05 μm to 1 μm, particularly preferably 0.1 μm to 1 μm. In case when the particle size of the pigment is less than 0.01 μm, the resulting dispersion has an undesirable stability in a coating solution for heat-sensitive layer whereas, in case when the particle size exceeds 10 μm, the heat-sensitive layer becomes unfavorable in view of its uniformity.

As methods for dispersing the pigment, known dispersing techniques which are used for producing ink or toner may be used. Examples of dispersing machines include an ultrasonic dispersing machine, a sand mill, an attriter, a pearl mill, a super mill, a ball mill, an impeller, a disperser, a KD mill, a colloid mill, a dynatron, a tripple roll mill and a pressurized kneader. Detailed descriptions are given in Saishin Ganryo Oyou Gijutsu (Newest Application Techniques for Pigments), CMC Publishing Co., Ltd. (1986).

Examples of usable dyes include commercially available dyes and known dyes described in the literature (e.g., Senryo Binran (Handbook of Dyes) edited by Yuki Gosei Kagaku Kyokai (1970)). Specific examples of usable dyes include azo dyes, metal complex azo dyes, pyrazolone azo dyes, anthraquinone dyes, phthalocyanine dyes, carbonium dyes, quinoneimine dyes, methine dyes, and cyanine dyes.

In the invention, pigments and dyes which absorb an infrared or near infrared ray are particularly preferred in view of being suitable for a laser emitting an infrared or near infrared ray.

Carbon black is preferably used as a pigment which absorbs an infrared or near infrared ray. Also, examples of the dyes which absorb an infrared or near infrared ray include the cyanine dyes described, e.g., in JP-A-58-125246, JP-A-59-84356, JP-A-59-202829 and JP-A-60-78787, methine dyes described, e.g., in JP-A-58-173696, JP-A-58-181690 and JP-A-58-194595, napahthoquinone dyes described, e.g., in JP-A-58-112793, JP-A-58-224793, JP-A-59-48187, JP-A-59-73996, JP-A-60-52940 and JP-A-60-63744, squarylium dyes described, e.g., in JP-A-58-112792, and cyanine dyes described in British Patent 434,875.

Also, the near infrared-absorbing sensitizers described in U.S. Pat. No. 5,156,938 are preferably used. The substituted arylbenzo(thio)pyrylium salts described in U.S. Pat. No. 3,881,924; the trimethinethiapyrylium salts described in JP-A-57-142645 (U.S. Pat. No. 4,327,169); the ppyrylium compounds described in JP-A-58-181051, J-A-58-220143, JP-A-59-41363, JP-A-59-84248, JP-A-59-84249, JP-A-59-146063, JP-A-59-146061, cyanine dyes described in JP-A-59-216146; pentamethinethiopyrylium salts described in U.S. Pat. No. 4,283,475; and pyrylium compounds disclosed in JP-B-5-13514 (the term “JP-B” as used herein means an “examined Japanese patent publication”) and JP-B-5-19702; and commercially available dyes such as Epolight III-178, Epolight III-130 and Epolight III-125 (made by Epolin, Inc) are particularly preferably used.

Other examples of especially preferred dyes are near infrared-absorbing dyes described in U.S. Pat. No. 4,756,993 as formulae (I) and (II).

The pigments or dyes may be incorporated in an amount of 0.01 to 50% by weight, preferably 0.1 to 10% by weight, and particularly preferably 0.5 to 10% by weight in case of the dyes or 3.1 to 10% by weight in case of the pigments, based on the total solid content of the heat-sensitive layer.

In case when the amount of the pigment or the dye is less than 0.01% by weight, the sensitivity decreases whereas, in case when the amount exceeds 50% by weight, uniformity of the heat-sensitive layer is deteriorated, leading to a poor durability of the heat-sensitive layer. The dyes or pigments may be incorporated together with other components into the same layer or into a layer separately provided in a case where two heat-sensitive layers are present.

Now, other components incorporated into the heat-sensitive layer of the positive-working lithographic printing plate precursor for use in the method of the invention are described below.

As the heat-sensitive layer, any one may be used that undergoes change in solubility to a developing solution before and after exposure. Examples of the compound to be contained therein include o-quinonediazide compounds. For instance, in the case of a heat-sensitive layer containing an alkali-soluble resin and the o-quinonediazide compound, the o-quinonediazide compound is a compound having at least one o-quinonediazide group and preferably increases solubility in an alkaline aqueous solution upon exposure to active rays.

As such compounds, compounds having various structures are known, and detailed descriptions are given in J. KOSAR, Light-Sensitive Systems, John Wiley & Sons, Inc. (1965), pp.336 to 352. As light-sensitive compounds contained in the heat-sensitive layer, sulfonic esters between various hydroxyl compounds and o-benzoquinonediazide or o-naphthoquinonediazide are particularly preferred.

Examples of the o-quinonediazide compounds as described above include an ester between 1,2-naphthoquinone-2-diazido-5-sulfonyl chloride and a phenol-formaldehyde resin or cresol-formaldehyde resin; an ester between 1,2-naphthoquinone-2-diazido-5-sulfonyl chloride and a pyrogallol-acetone resin described in U.S. Pat. No. 3,635,709; an ester between 1,2-naphthoquinone-2-diazido-5-sulfonyl chloride and a resorcin-benzaldehyde resin described in JP-B-63-13528; an ester between 1,2-naphthoquinone-2-diazido-5-sulfonyl chloride and a resorcin-pyrrogallol-acetone co-condensation resin described in JP-B-62-44257; a product obtained by esterifying a polyester having a terminal hydroxyl group with 1,2-naphthoquinone-2-diazido-5-sulfonyl chloride described in JP-B-56-45127; a product obtained by esterifying a homopolymer of N-(4-hydroxyphenyl)methacrylamide or copolymer of N-(4-hydroxyphenyl)methacrylamide and other copolymerizable monomer with 1,2-naphthoquinone-2-diazido-5-sulfonyl chloride described in JP-B-50-24641; an ester between 1,2-naphthoquinone-2-diazido-5-sulfonyl chloride and a bisphenol-formaldehyde resin described in JP-B-54-29922; a product obtained by esterifying a homopolymer of p-hydroxystyrene or copolymer of p-hydroxystyrene and other copolymerizable monomer with 1,2-naphthoquinone-2-diazido-5-sulfonyl chloride described in JP-B-52-36043; and an ester between 1,2-naphthoquinone-2-diazido-5-sulfonyl chloride and polyhydroxybenzophenone.

Other known o-quinonediazide compounds usable in the invention include those described in JP-A-63-80254, JP-A-58-5737, JP-A-57-111530, JP-A-57-111531, JP-A-57-114138, JP-A-57-142635, JP-A-51-36129, JP-B-62-3411, JP-B-62-51459, and JP-B-51-483.

The amount of o-quinonediazide compound added is ordinarily 5 to 60% by weight, preferably 10 to 40% by weight based on the total solid content of the heat-sensitive layer.

To the heat-sensitive layer may further be added, if desired, a cyclic acid anhydride for incresing sensitivity, a printing-out agent for obtaining a visible image immediately after exposure, and a dye as an image-coloring agent.

It is preferred to add a cyclic acid anhydride, a phenol or an organic acid for increasing sensitivity.

Examples of the cyclic acid anhydride include, as described in U.S. Pat. No. 4,115,128, phthalic anhydride, tetrahydrophthalic anhydride, hexahydrophthalic anhydride, 3,6-endoxy-Δ4-tetrahydrophthalic anhydride, tetrachlorophthalic anhydride, maleic anhydride, chloromaleic anhydride, α-phenylmaleic anhydride, succinic anhydride, and pyromellitic anhydride. Examples of the phenols include bisphenol A, p-nitrophenol, p-ethoxyphenol, 2,3,4-trihydroxybenzophenone, 4-hydroxybenzophenone, 2,4,4′-trihydroxybenzophenone, 4,4′,4″-trihydroxytriphenylmethane, and 4,4′,3″,4″-tetrahydroxy-3,5,3′,5′-tetramethyltriphenylmethane.

Examples of the organic acids include sulfonic acids, sulfinic acids, alkylsulfuric acids, phosphonic acids, phosphinic acids, phosphates and carboxylic acids as described, for example, in JP-A-60-88942 and JP-A-2-96755. Specific examples thereof include p-toluenesulfonic acid, dodecylbenzenesulfonic acid, p-toluenesulfinic acid, ethylsulfuric acid, phenylphosphonic acid, phenylphosphinic acid, phenyl phosphate, diphenyl phosphate, benzoic acid, isophthalic acid, adipic acid, p-toluic acid, 3,4-dimethoxybenzoic acid, phthalic acid, terephthalic acid, 1,4-cyclohexene-2,2-dicarboxylic acid, erucic acid, lauric acid, n-undecanoic acid and ascorbic acid.

The content of the cyclic acid anhydride, phenol or organic acid in the heat-sensitive layer is preferably 0.05 to 15% by weight, more preferably 0.1 to 5% by weight.

As the printing-out agent for obtaining a visible image immediately after exposure, there is illustrated a combination of a light-sensitive compound capable of releasing an acid upon exposure and an organic dye which forms a salt with the acid to undergo change in color.

Examples of the light-sensitive compound capable of releasing an acid upon exposure include o-naphthoquinonediazido-4-sulfonic acid halogenides described in JP-A-50-36209; trihalomethyl-2-pyrone and trihalomethyl-s-triazine described in JP-A-53-36223; various o-naphthoquinonediazide compounds described in JP-A-55-62444; 2-trihalomethyl-5-aryl-1,3,4-oxadiazole compounds described in JP-A-55-77742; and diazonium salts.

These compounds may be used alone or in combination. The amount of the compound is preferably 0.3 to 15% by weight based on the total solid content of the heat-sensitive layer.

Also, in the heat-sensitive layer is used at least one organic dye which causes interaction with a light-decomposition product of the compound which generates an acidic substance upon photolysis.

As the organic dye, there may be used diphenylmethane dyes, triarylmethane dyes, thiazine dyes, oxazine dyes, phenazine dyes, xanthene dyes, anthraquinone dyes, iminonaphthoquinone dyes and azomethine dyes. Specific examples thereof include Brilliant Green, Eosine, Ethyl Violet, Erythrosine B, Methyl Green, Crystal Violet, Basic Fuchsine, phenolphthalein, 1,3-diphenyltriazine, Alizarine Red S, Tymolphthalein, Methyl Violet 2B, Quinaldine Red, Rose Bengale, Tymolsulfophthalein, Xylenol Blue, Methyl Orange, Orange IV, diphenylthiocarbazone, 2,7-dichlorofluorescein, Paramethyl Red, Congo Red, Benzopurpurine 4B, α-Naphthyl Red, Nile Blue 2B, Nile Blue A, phenacetaline, Methyl Violet, Malachite Green, Parafucsine, Oil Blue #603 (made by Orient Chemical Industries Co., Ltd), Oil Pink #312 (made by Orient Chemical Industries Co., Ltd.), Oil Red 5B (made by Orient Chemical Industries Co., Ltd.), Oil Scarlet #308 (made by Orient Chemical Industries Co., Ltd.), Oil Red OG (made by Orient Chemical Industries Co., Ltd.), Oil Red RR (made by Orient Chemical Industries Co., Ltd.), Oil Green #502 (made by Orient Chemical Industries, Co., Ltd.), Spiron Red BEH Special (made by Hodogaya Kagaku Kogyo K.K.), Victoria Pure Blue BOH (made by Hodogaya Kagaku Kogyo K.K.), Patent Pure Blue (made by Sumitomo Mikuni Kagaku Kogyo K.K.), Sudan Blue II (made by BASF), m-Cresol Purple, Cresol Red, Rhodamine B, Rhodamine 6G, Fast Acid Violet R, Sulforhodamine B, Auramine, 4-p-diethylaminophenyliminonaphthoquinone, 2-carboxyanilino-4-p-diethylaminophenyliminonaphthoquinone, 2-carbostearylamino-4-p-dihydroxyethylaminophenyliminonaphthoquinone, p-methoxybenzoyl-p′-diethylamino-o′-methylphenyliminoacetanilide, cyano-p-diethylaminophenyliminoacetanilide, 1-phenyl-3-methyl-4-p-diethylaminophenylimino-5-pyrazolone, 1-β-naphthyl-4-p-diethylaminophenylimino-5-pyrazolone, etc.

Particularly preferred organic dyes are the triarylmethane dyes. Among the triarylmethane dyes, dyes which have a sulfonic acid compound as a counter ion as described in JP-A-62-2932471 and Japanese Patent 2969021 are particularly useful.

The organic dyes may be used alone or in combination. The amount of organic dye is preferably 0.3 to 15% by weight based on the total solid content of the heat-sensitive layer. Also, the organic dye may be used in combination with other dyes or pigments, if desired. The other dyes or pigments are used in an amount of 70% by weight or less, more preferably 50% by weight or less, based on the total weight of the dyes and pigments.

In addition, various additives may be added to the heat-sensitive layer for various purposes, for example, various resins having hydrophobic groups for improving ink-receptive property of image areas, e.g., an octylphenol-formaldehyde resin, a tert-butylphenol-formaldehyde resin, a tert-butylphenol-benzaldehyde resin, a rosin-modified novolak resin and o-naphthoquinonediazidosulfonic acid esters of the modified novolak resin or a plasticizer for improving flexibility of a coating film, e.g., dibutyl phthalate, dioctyl phthalate, butyl glycolate, tricresyl phosphate and dioctyl adipate. The additive is added in an amount of preferably 0.01 to 30% by weight based on the total solid content of the heat-sensitive layer.

Further, known resins for more improving abrasion resistance of the film may be added to the heat-sensitive layer. Examples of such resins include polyvinyl acetal resin, polyurethane resin, epoxy resin, vinyl chloride resin, nylon, polyester resin and acrylic resin. The resins may be used alone or in combination. The amount thereof is preferably 2 to 40% by weight based on the total solid content of the heat-sensitive layer.

Also, in order to enlarge latitude of development, nonionic surfactants as described in JP-A-62-251740 and JP-A-4-68355 and amphoteric surfactants as described in JP-A-59-121044 and JP-A-4-13149 may be added to the heat-sensitive layer. Specific examples of the nonionic surfactants include sorbitan tristearate, sorbitan monopalmitate, sorbitan trioleate, stearyl monoglyceride, polyoxyethylenesorbitan monooleate and polyoxyethylene nonyl phenyl ether, and specific examples of the amphoteric surfactants include alkyldi(aminoethyl)glycine, alkylpolyaminoetylglycine hydrochloride, Amorgen K (trade name; made by Daiichi Kogyo Seiyaku K.K.: N-tetradecyl-N,N-betaine type), 2-alkyl-N-carboxyethyl-N-hydroxyethylimidazolinium betaine and Revon 15 (trade name; made by Sanyo Chemical Industries, Ltd.; alkylimidazoline type).

The content of the nonionic surfactant or amphoteric surfactant is preferably from 0.05 to 15% by weight, more preferably from 0.1 to 5% by weight based on the total solid content of the heat-sensitive layer.

Also, to the heat-sensitive layer may be added a yellow dye, preferably a yellow dye having an absorbance at 417 nm of 70% or more of an absorbance at 436 nm.

Also, in the heat-sensitive layer may be incorporated a fluorine-containing polymer of (A), (B) or (C) described below.

(A) fluorine-containing polymer containing as a polymerizable monomer, a (meth)acrylate monomer having 2 or 3 perfluoroalkyl groups each containing 3 to 20 carbon atoms;

(B) fluorine-containing polymer containing as copolymerizable component, at least the following monomers (1) to (3):

(1) an addition-polymerizable fluorine-containing monomer having in its side chain a fluoroaliphatic group wherein hydrogen atoms on the carbon atoms are substituted by fluorine atoms;

(2) a monomer represented by any one of the following formulae [1] to [4]:

CH₂═CA¹[CO—W—R²] [1]

CH₂═CA¹[O—CO—R³] [2]

CH₂═CA¹[U] [3]

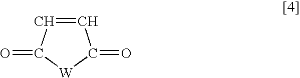

wherein A¹ represents a hydrogen atom, a halogen atom or an alkyl group, W represents oxygen or —NR¹—, R¹ represents a hydrogen atom, an alkyl group or an aryl group, R² represents an optionally substituted alkyl group or an optionally substituted aryl group, R³ represents an alkyl group or an aryl group, U represents a cyano group, an aryl group, an alkoxy group, an aryloxy group, an acyloxymethyl group, a nitrogen-containing hetero ring or —CH₂OCOR³ (wherein R³ has the same meaning as defined above); and

(3) an addition-polymerizable monomer having an acidic group wherein an acidic hydrogen atom is bonded to a nitrogen atom, and

(C) a copolymer of (i) (meth)acrylate containing a fluoroaliphatic group (Rf group) which contains 3 to 20 carbon atoms and fluorine atoms in a content of 40% by weight or more and in which at least 3 carbon atoms at the terminal are sufficiently fluorinated and (ii) poly(oxyalkylene) (meth)acrylate, with the content of the Rf group-containing (meth)acrylate monomer unit being 25 to 70% by weight based on the weight of the copolymer.

The above fluorine-containing polymer (A) contains, as a polymerizable component, (meth)acrylate monomer containing 2 or 3 perfluoroalkyl groups each containing 3 to 20 carbon atoms (hereinafter also referred to as “fluorine-containing monomer (A)”). The fluorine-containing monomer (A) is not particularly limited as long as the 2 or 3 perfluoroalkyl groups each containing 3 to 20 carbon atoms are bonded to acryloyl or methacryloyl group through a 4-valent linking group.

In the invention, when (meth)acrylate monomer containing only one perfluoroalkyl group or (meth)acrylate monomer containing a perfluoroalkyl group having less than 3 carbon atoms is used, the improvement in discrimination of image may not be achieved in some cases, whereas when (meth)acrylate monomer containing a perfluoroalkyl group having more than 20 carbon atoms is used the sensitivity may decrease in some cases.

The fluorine-containing polymer (A) preferably contains as a polymerizable component, a fluorine-containing monomer represented by the following formula (I):

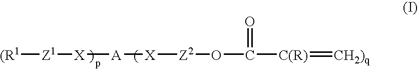

In formula (I), R¹ represents a perfluoroalkyl group containing 3 to 20 carbon atoms or a perfluoroalkenyl group containing 3 to 20 carbon atoms. These groups may be straight, branched, cyclic or a combination thereof, or may be those wherein the main chain is interrupted by oxygen atom, e.g., (CF₃)₂CFOCF₂CF₂—.

Z¹ represents —(CH₂)n— (wherein n represents an integer of 1 to 6) or a group represented by formula shown below (wherein R² represents a hydrogen atom or an alkyl group containing 1 to 10 carbon atoms, and m and n each represents an integer of 2 to 6). In the general formula (I), two or three Z¹s may be two or three linking groups different from each other.

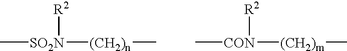

Z² represents —(CH₂)ₘ— (wherein m represents an integer of 2 to 6) or a group represented by the following formula:

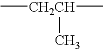

R represents a hydrogen atom, a methyl group or a halogen atom (e.g., Cl, Br). X represents a divalent linking group represented by the formula shown below (wherein Y represents a divalent group containing 15 or less carbon atoms and accounts for 35 to 65% in weight proportion of the group X):

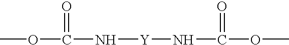

Typical examples of the divalent linking group represented by Y include the following groups:

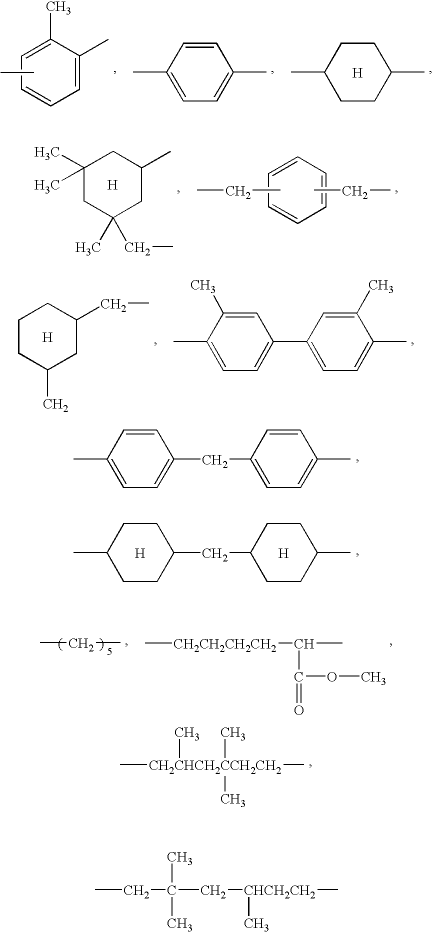

In formula (I), p and q each represents an integer satisfying p+q=4 (provided that p is 2 or 3). A represents a 4-valent linking group represented by the following formula:

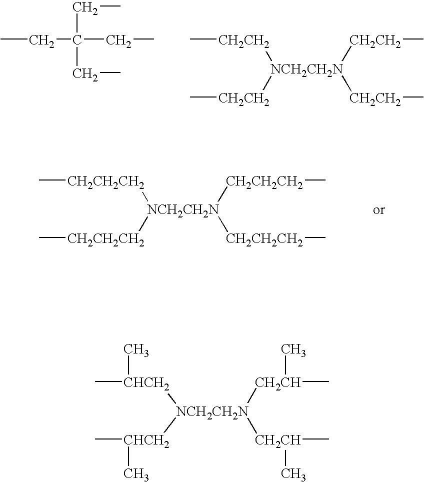

Specific examples of the fluorine-containing monomer (A) are illustrated below, however, the invention should not be limited thereto.

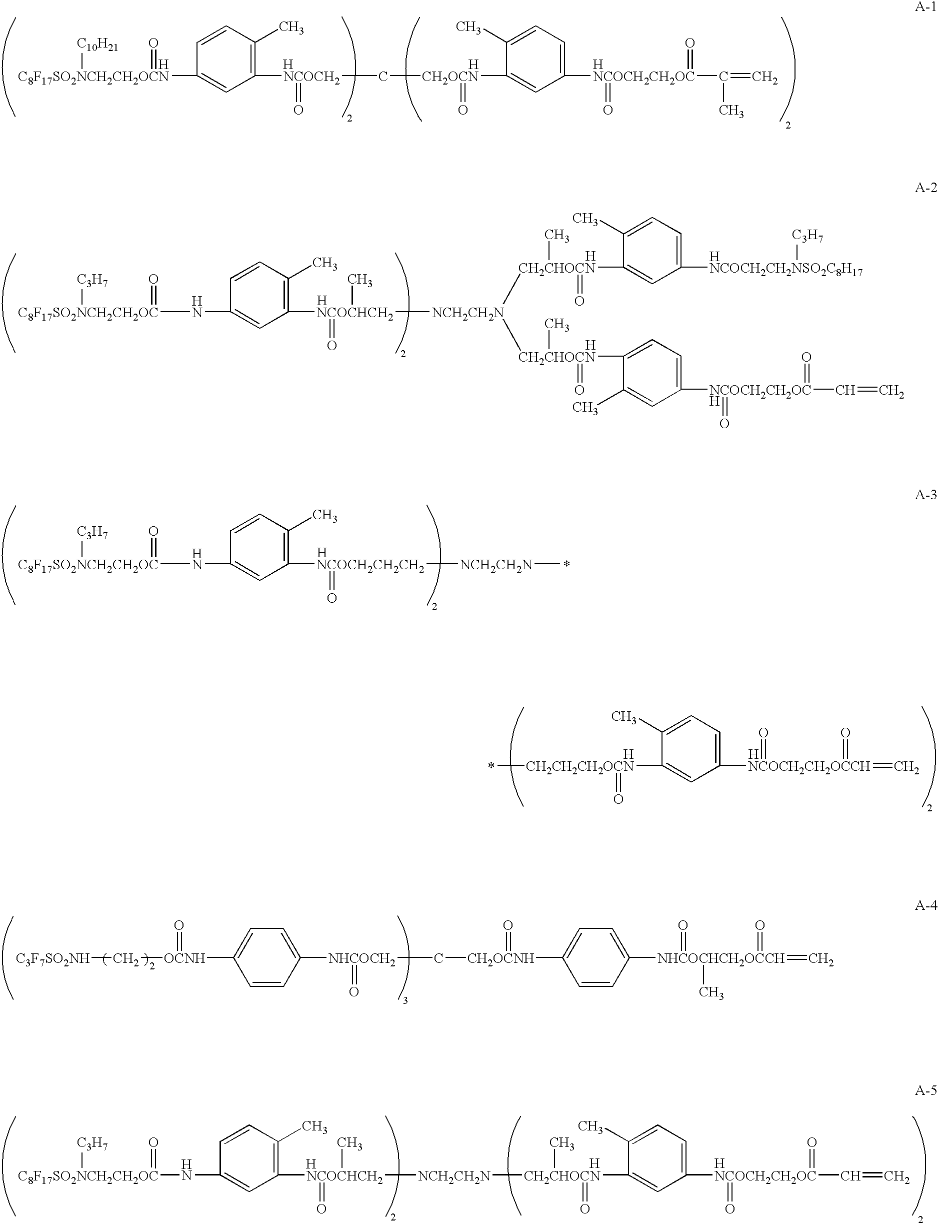

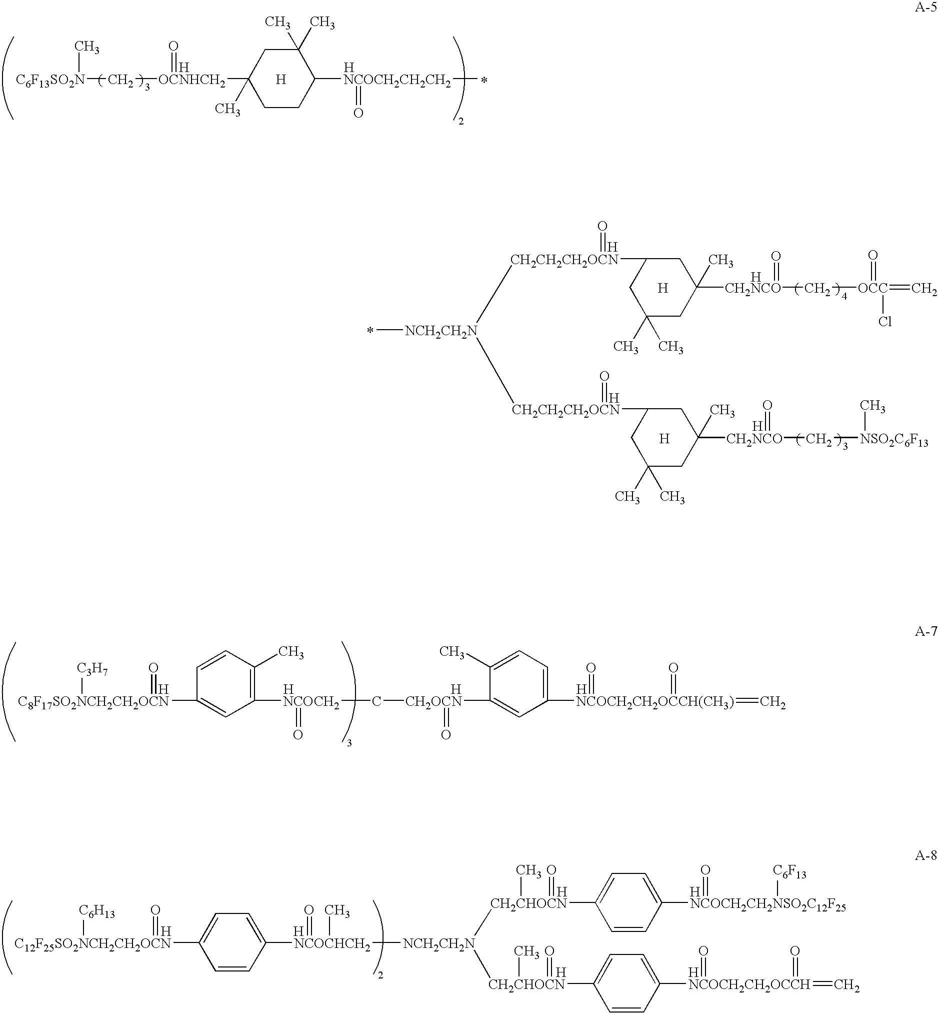

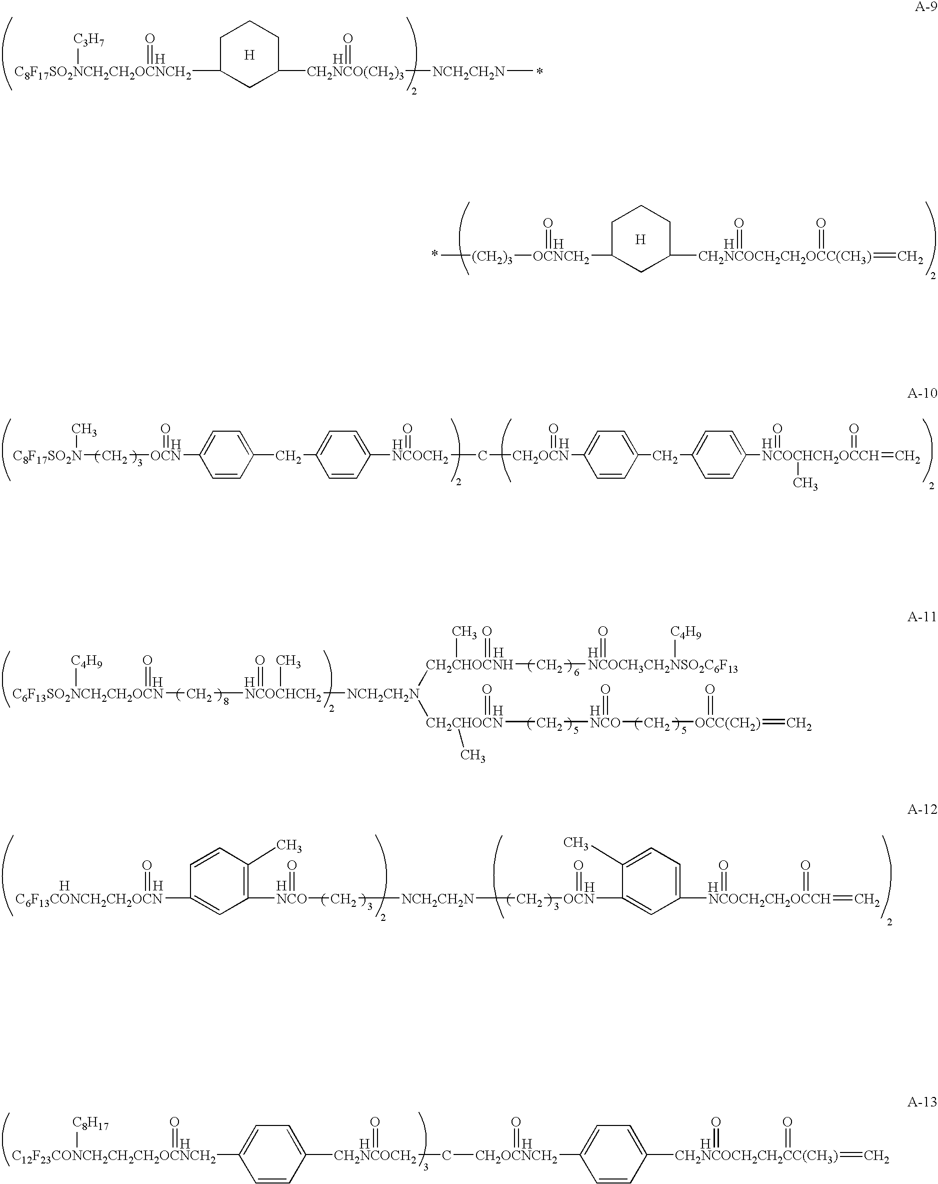

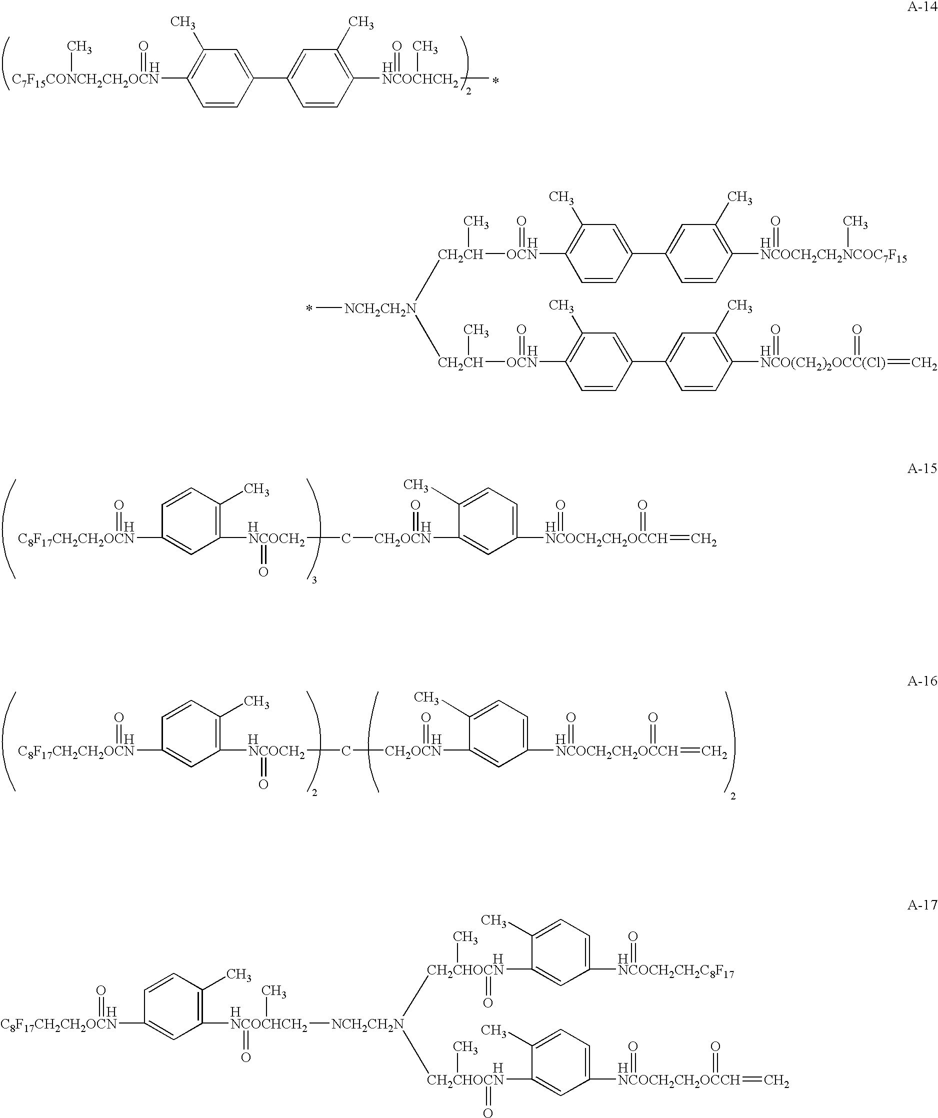

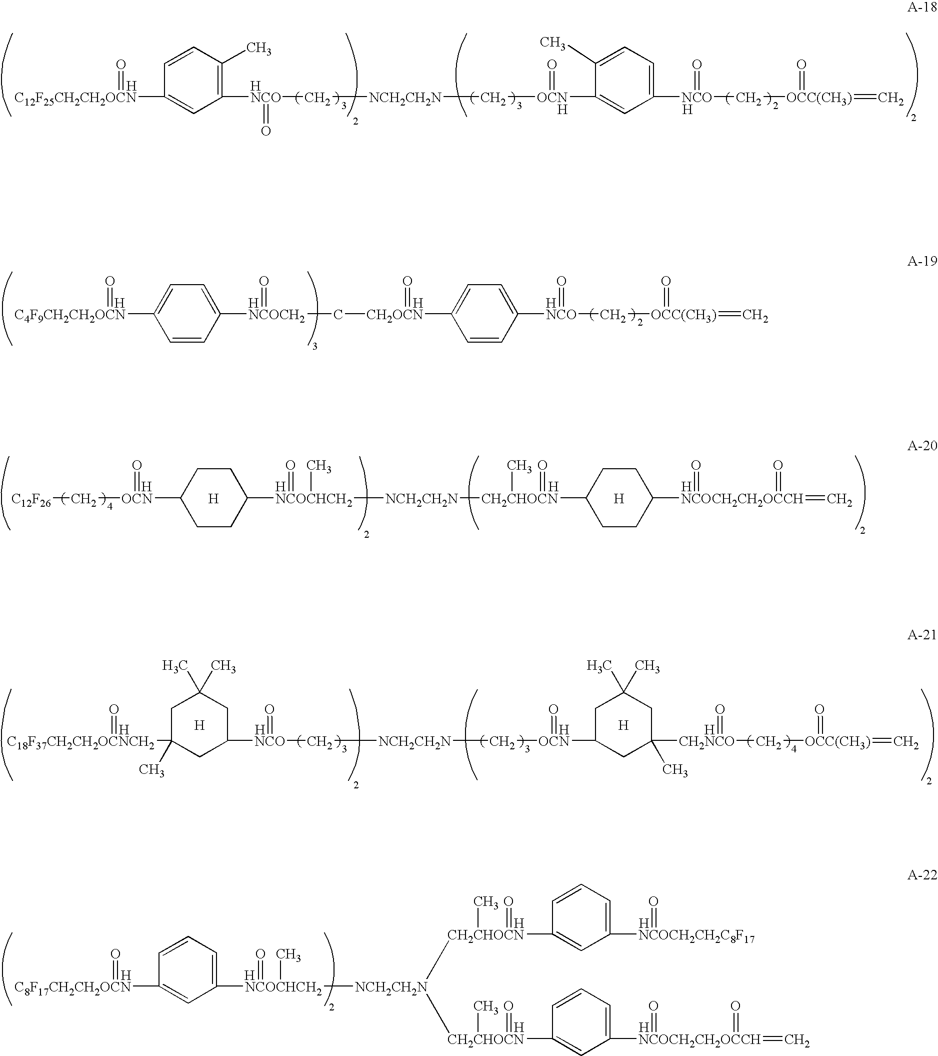

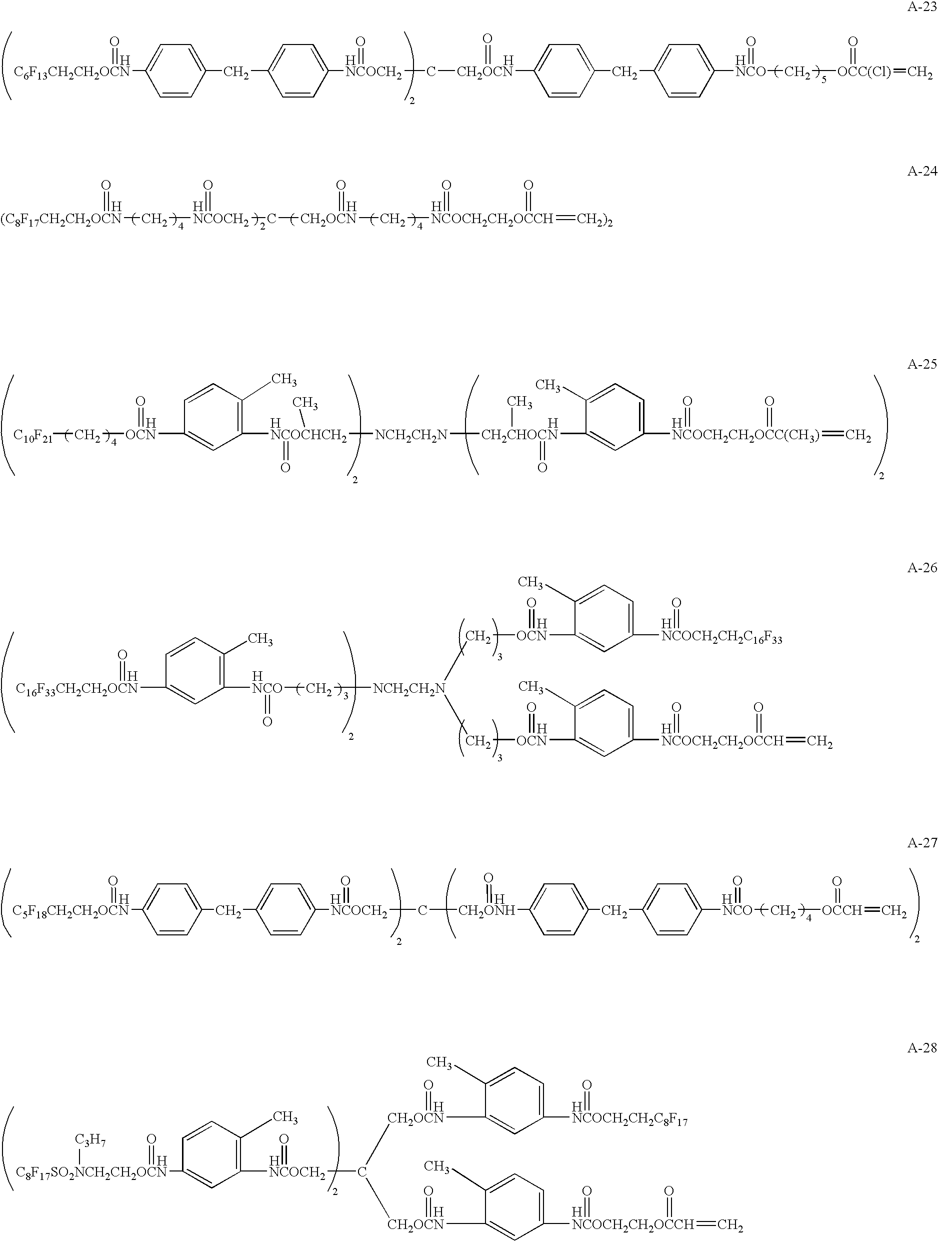

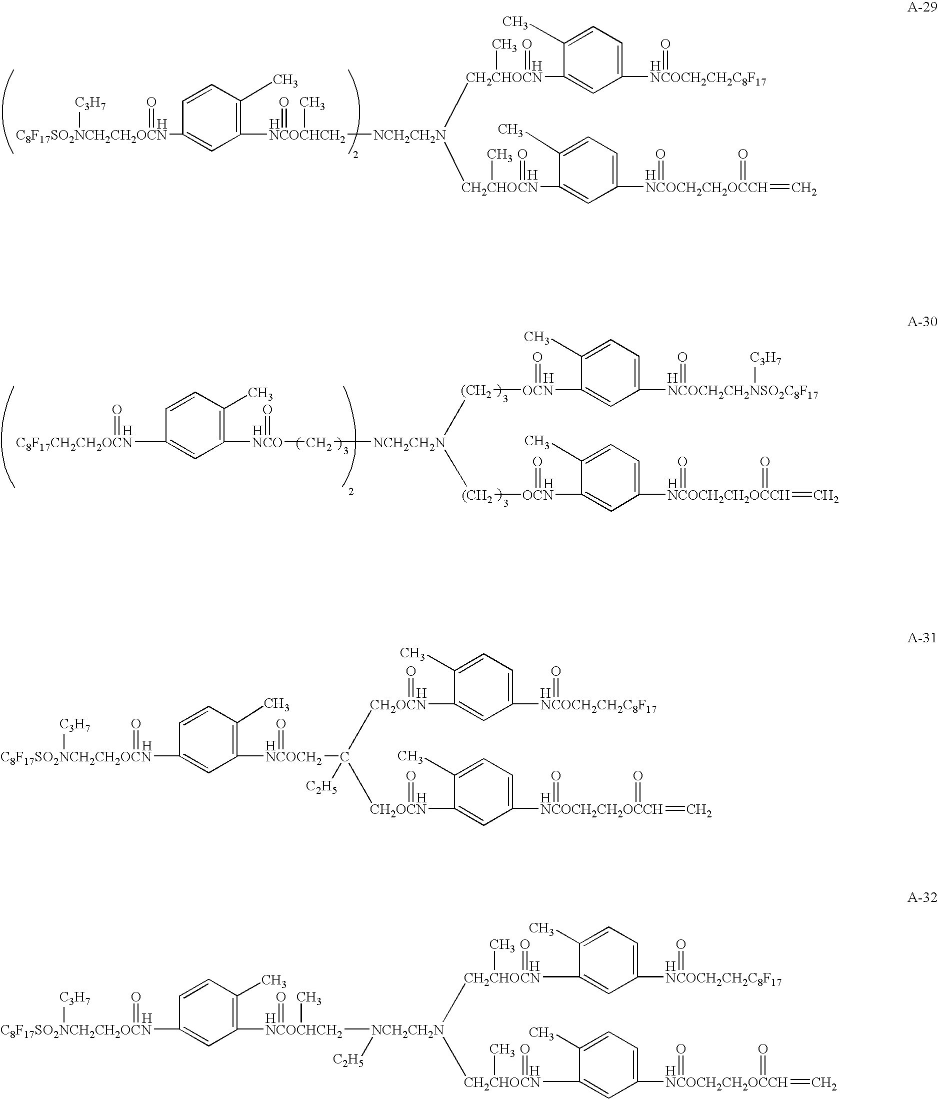

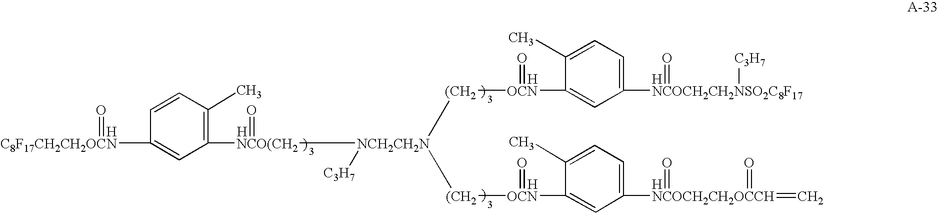

Also, the fluorine-containing polymer (A) comprises a copolymer between a (meth)acrylate monomer having 2 or 3 perfluoroalkyl groups each containing 3 to 20 carbon atoms and a hydrocarbyl (meth)acrylate monomer. In this case, two or more of the hydrocarbyl (meth)acrylate monomers may be used.

The hydrocarbyl (meth)acrylate monomer has one or two acryloyl groups and may be appropriately selected from those which are known in the art (e.g., compounds described in Seishi Kato and Shoji Nakahara, UV Koka Gijutsu Nyumon published by Kobunshi Kankokai, Table 10 on pages 34 and 35, Table 16 on pages 46 to 48, Table 20 on page 57 and Table 60 on pages 170 to 172). The hydrocarbyl (meth)acrylate monomer is exemplified by the Monomers B-1 to B-8 shown below. Of the monomers, B-1, B-2 and B-4 are particularly preferably used.

CH₂═C(R³)COOR⁴ B-1

CH₂═C(R³)COOCH₂CH₂OH B-2

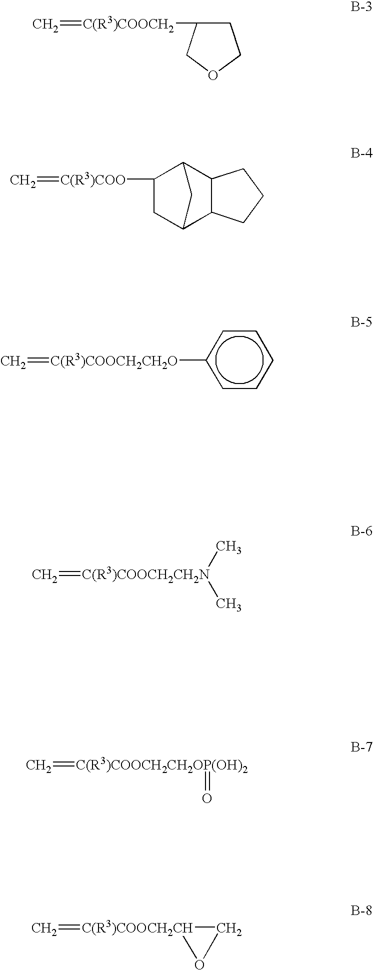

(wherein R³ represents —H or —CH₃, and R⁴ represents an alkyl group having 1 to 20 carbon atoms)

The molecular weight of the fluorine-containing polymer (A) is not particularly limited, but is preferably 3,000 to 200,000, more preferably 4,000 to 100,000 in terms of weight average molecular weight.

The amount of the fluorine-containing polymer (A) added is preferably 0.01 to 10% by weight, more preferably 0.1 to 5% by weight, based on the total solid content of the heat-sensitive layer.

Now, the fluorine-containing polymer (B) (hereinafter also referred to as “fluorine-containing polymer (B)”) is described below.

The fluorine-containing polymer (B) contains at least the aforementioned (1) to (3) as copolymerizable components.

The fluoroaliphatic group in the component (1) wherein hydrogen atoms on the carbon atoms are substituted by fluorine atoms is ordinarily a saturated monovalent or divalent aliphatic group. The fluoroaliphatic group includes straight, branched and cyclic fluoroaliphatic groups. In order to fully exhibit its effects, the fluoroaliphatic group contains 3 to 20 carbon atoms, preferably 6 to 12 carbon atoms and has fluorine atoms bonded to carbon atom in a content of 40% by weight or more, preferably 50% by weight or more, based on the total weight of the fluorine-containing monomer. A preferred fluoroaliphatic group is a perfluoroaliphatic group (hereinafter also abbreviatedly referred to as a Rf group) substantially completely or fully fluorinated, for example, as CₙF₂ₙ₊₁— (wherein n represents an integer of 1 or more, preferably 3 or more).

As an addition-polymerizable portion in the addition-polymerizable monomer of the component (1) having the fluoroaliphatic group wherein the hydrogen atoms on carbon atoms are substituted by fluorine atoms, a radically polymerizable unsaturated group is used. The addition-polymerizable portion preferably includes acrylates, methacrylates, acrylamides, methacrylamides, styrene, vinyl and the derivatives thereof. Specific examples of acrylate or methacrylate having the fluoroaliphatic group include compounds represented by Rf—R′—OOC—C(R″)═CH₂ (wherein R′ represents, for example, a single bond, alkylene, sulfonamidoalkylene or carbonamidoalkylene, and R″ represents a hydrogen atom, a methyl group, a halogen atom or a perfluoroaliphatic group).

Specific examples thereof include those described in U.S. Pat. Nos. 2,803,615, 2,642,416, 2,826,564, 3,102,103, 3,282,905 and 3,304,278, JP-A-6-256289, JP-A-62-1116, JP-A-62-48772, JP-A-63-77574 and JP-A-62-36657 and those described in Nippon Kagaku Kaishi, 1985 (No. 10), pp.1884 to 1888. Also, in addition to the fluoroaliphatic group-containing monomer, fluoroaliphatic group-containing macromers described in Reports Res. Lab. Asahi Glass Co. Ltd., vol.34, pp. 27 to 34 (1984) may preferably be used. Further, as the fluoroaliphatic group-containing monomer, a mixture thereof different in the length of the perfluoroalkyl group as represented by the following structural formula:

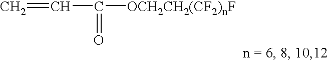

The content of these fluoroaliphatic group-containing monomers to be used in the fluorine-containing polymer (B) is in a range of 3 to 70% by weight, preferably 7 to 40% by weight, based on the weight of the polymer.

The monomer used as the component (2) is represented by any one of the following structures [1] to [4]:

CH₂═CA¹[CO—W—R²] [1]

CH₂═CA¹[O—CO—R³] [2]

CH₂═CA¹[U] [3]

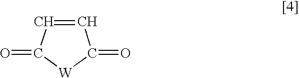

wherein A¹ represents a hydrogen atom, a halogen atom or an alkyl group, W represents oxygen or —NR¹—, R¹ represents a hydrogen atom, an alkyl group or an aryl group, R² represents an optionally substituted alkyl group or an optionally substituted aryl group, R³ represents an alkyl group or an aryl group, and U represents a cyano group, an aryl group, an alkoxy group, an aryloxy group, an acyloxymethyl group, a nitrogen-containing hetero ring or —CH₂OCOR³ (wherein R³ has the same meaning as defined above). Preferred monomers represented by the structures [1] to [4] are those wherein A¹ represents a hydrogen atom, a halogen atom or an alkyl group containing 1 to 4 carbon atoms, W represents oxygen or —NR¹—, R¹ represents a hydrogen atom, an alkyl group containing 1 to 20 carbon atoms or an aryl group containing 6 to 20 carbon atoms, R²represents an optionally substituted alkyl group containing 1 to 8 carbon atoms or an optionally substituted aryl group, R³ represents an alkyl group containing 1 to 20 carbon atoms or an aryl group containing 6 to 20 carbon atoms, U represents a cyano group, an aryl group, an alkoxy group, an aryloxy group, an acyloxymethyl group, a nitrogen-containing hetero ring or —CH₂OCOR³ (wherein R³ has the same meaning as defined above).

In the case where R² represents an optionally substituted alkyl group, examples of the substituent include a halogen atom such as fluorine, chlorine or bromine, a hydroxyl group, an alkoxy group such as methoxy or ethoxy, an aryloxy group such as phenoxy, a cyano group, an amido group such as acetamido, and an alkoxycarbonyl group such as ethoxycarbonyl. In the case where R² represents an optionally substituted aryl group, examples of the substituent include those described above for the alkyl group and a methyl group.

Preferred specific examples of the component (2) include (meth)acrylates such as methyl (meth)acrylate, ethyl (meth)acrylate, propyl (meth)acrylate, butyl (meth)acrylate, amyl (meth)acrylate, 2-ethylhexyl (meth)acrylate, octyl (meth)acrylate, 2-chloroethyl (meth)acrylate, cyclohexyl (meth)acrylate, 2-hydroxyethyl (meth)acrylate, 2-hydroxypropyl (meth)acrylate, 2-hydroxybutyl (meth)acrylate, diethylene glycol mono(meth)acrylate, 2-hydroxy-3-phenoxypropyl (meth)acrylate, glycidl (meth)acrylate, diethylaminoethyl (meth)acrylate, furfuryl (meth)acrylate, tetrahydrofurfuryl (meth)acrylate, phenyl (meth)acrylate, hydroxyphenyl (meth)acrylate, cresyl (meth)acrylate, naphthyl (meth)acrylate, benzyl (meth)acrylate and methoxybenzyl (meth)acrylate; (meth)acrylamides such as (meth)acrylamide, N-ethyl (meth)acrylamide, N-propyl (meth)acrylamide, N-butyl (meth)acrylamide, N-hexyl (meth)acrylamide, N-octyl (meth)acrylamide, N-cyclohexyl (meth)acrylamide, N-methylol (meth)acrylamide, N-hydroxyethyl (meth)acrylamide, N-benzyl (meth)acrylamide, N-phenyl (meth)acrylamide, N-nitrophenyl (meth)acrylamide, N-toyl (meth)acrylamide, N-hydroxyphenyl (meth)acrylamide, N,N-dimethyl (meth)acrylamide, N,N-diethyl (meth)acrylamide and N,N-dicyclohexyl (meth)acrylamide; N-substituted maleimides such as N-methylmaleimide, N-ethylmaleimide, N-propylmaleimide, N-butylmaleimide, N-pentylmaleimide, N-n-hexylmaleimide, N-laurylmaleimide, N-stearylmaleimide, N-cyclohexylmaleimide, N-phenylmaleimide, N-chlorophenylmaleimide, N-tolylmaleimide, N-hydroxymaleimide and N-benzylmaleimide; allyl compounds such as allyl acetate, allyl caproate, allyl stearate and allyloxyethanol; vinyl ethers such as ethyl vinyl ether, propyl vinyl ether, butyl vinyl ether, octyl vinyl ether, methoxyethyl vinyl ether, ethoxyethyl vinyl ether, 2-chloroethyl vinyl ether, hydroxyethyl vinyl ether, benzyl vinyl ether, tetrahydrofurfuryl vinyl ether, phenyl vinyl ether, tolyl vinyl ether and diethylaminoethyl vinyl ether; vinyl esters such as vinyl acetate, vinyl butyrate, vinyl caproate, vinyl chloroacetate, vinyl methoxyacetate, vinyl phenyl acetate, vinyl acetoacetate, vinyl benzoate and vinyl chlorobenzoate; styrenes such as styrene, α-methylstyrene, methylstyrene, dimethylstyrene; chloromethylstyrene, ethoxymethylstyrene, hydroxystyrene, chlorostyrene and bromostyrene; N-vinylpyrrolidone; N-vinylpyridine; and acrylonitrile. Of these components (2), monomers represented by the structure [1] or [3] are particularly preferred.

As the acidic group in the component (3) which has an acidic hydrogen atom bonded to a nitrogen atom, any acidic group known by literatures may be used. As the literature describing the acidic group, there is illustrated J. A. Dean ed., Lange's Handbook of Chemistry, 3^{rd}. ed., McGraw-Hill Book Co. (1985). Of these acidic groups, specific examples of the partial structure of the acidic group wherein an acidic hydrogen atom is bound to a nitrogen atom include those represented by the following formula [A] to [G]:

—SO₂NH₂ [A]

—SO₂NH— [B]

—CONHSO₂— [C]

—CONHCO— [D]

—SO₂NHSO₂— [E]

—CONHSO₂NH— [F]

—NHCONHSO₂— [G]

In addition to these structures, nitrogen-containing hetero ring structure having a coupler structure described in JP-A-7-248628 are included as well. Examples of such nitrogen-containing hetero ring structure include those represented by the following [H] and [I]:

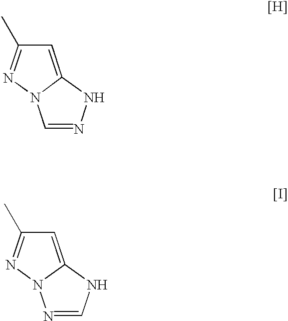

As an addition-polymerizable portion in the addition-polymerizable monomer of the component (3) which has an acidic hydrogen atom bonded to a nitrogen atom, a radically polymerizable unsaturated group is used. Of the addition-polymerizable portions, acrylate, methacrylate, acrylamide, methacrylamide, styrene, vinyl and the derivatives thereof are preferred. Examples of the preferred structure of the monomer containing the acidic group having an acidic hydrogen atom bonded to a nitrogen atom include the monomers having the structural unit represented by the following formula [5], [6] or [7]:

CH₂═CA²[(B)m—(X)₅—NH—Y] [5]

CH₂═CA²[CO—Z—E—SO₂.NH—R⁵] [6]

In the above formulae, A² represents a hydrogen atom, a halogen atom or an alkyl group containing 1 to 4 carbon atoms, B represents an arylene group, X represents —CO— or —SO₂—. In the case where X represents —SO₂—, Y represents a hydrogen atom, an alkyl group, an aryl group, —CO—R⁴ or —SO₂—R⁴ and, where X represents —CO—, Y represents —CO—R⁴ or —SO₂—R⁴. Z represents —NH—, —NR⁴— or —O—, E represents an arylene group or an alkylene group, R⁵ represents a hydrogen atom, an alkyl group or an aryl group, and m and s each represents 0 or 1, provided that m and s do not represent 0 at the same time. R⁴ represents an alkyl group or an aryl group. Or B and Y or E and R may be connected to each other to form a ring comprising non-metallic atoms.

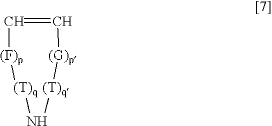

In the above formula, F and G each represents a phenylene group or an alkylene group, T represents —O—CO—, —CO— or —SO2—, p, p′, q and q′ each represents 0 or 1, with the proviso that q and q′ do not represent 0 at the same time.

In the foregoing general formulae [5] and [6], preferred examples of A² include a hydrogen atom and a methyl group. Preferred examples of the alkyl group represented by Y, R⁴ or R⁵ include alkyl groups containing 1 to 20 carbon atoms such as methyl, ethyl and isopropyl, and preferred examples of the aryl group represented by Y, R⁴ or R⁵ include aryl groups containing 6 to 18 carbon atoms such as phenyl and naphthyl. Preferred examples of the arylene group represented by B or E include phenylene and naphthylene, and preferred examples of the alkylene group represented by E include alkylene groups containing 1 to 20 carbon atoms such as methylene and ethylene.

The alkyl group and the aryl group represented by Y, R⁴ or R⁵ and the arylene group and the alkylene group represented by B or E may have a substituent. Examples of the substituent include a halogen atom such as fluorine, chlorine or bromine, an alkoxy group such as methoxy or ethoxy, an aryloxy group such as phenoxy, a cyano group, an amido group such as acetamido, an alkoxycarbonyl group such as an ethoxycarbonyl group and, further, an alkyl group containing 1 to 20 carbon atoms and an aryl group containing 6 to 18 carbon atoms. In the foregoing formula [7], preferred examples of F and G include those described for B or E above. Of the monomers of formulae [5] to [7], monomers of formulae [5] and [6] are more preferred.

The amount of the acidic group-containing monomer in the fluorine-containing polymer is in a range of 5 to 80% by weight, preferably 10 to 70% by weight, based on the weight of the polymer.

Specific examples of the structure of the monomer containing the acidic group wherein the acidic hydrogen atom is bonded to a nitrogen atom are illustrated below.

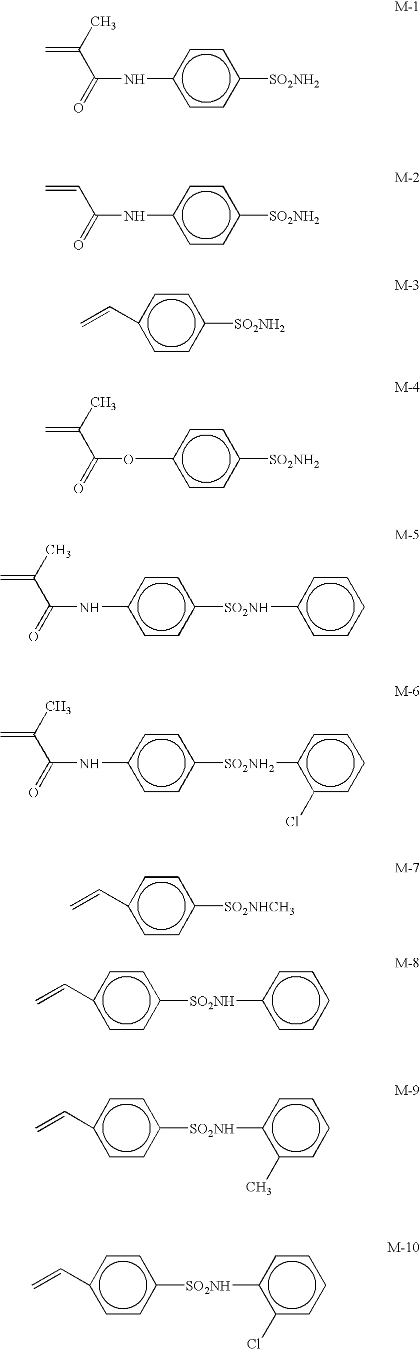

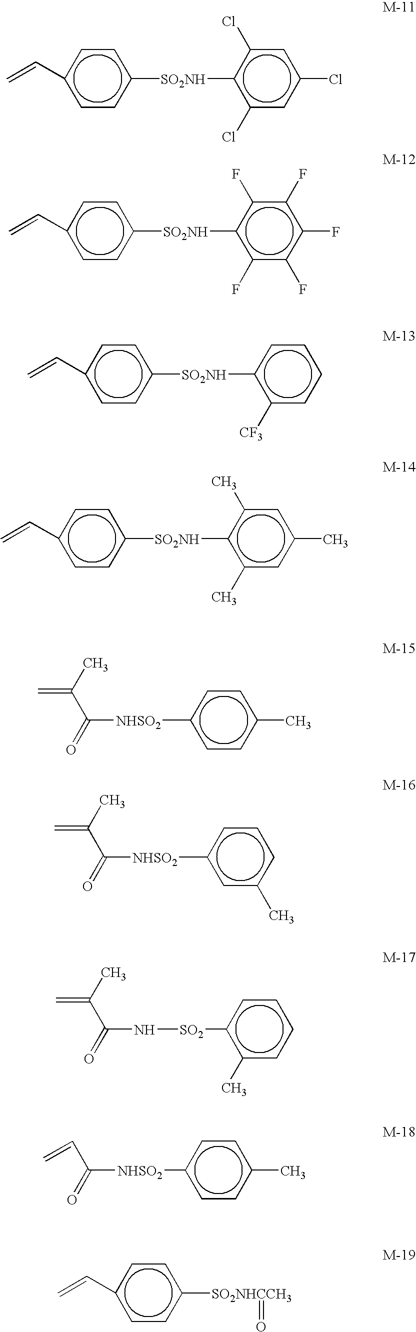

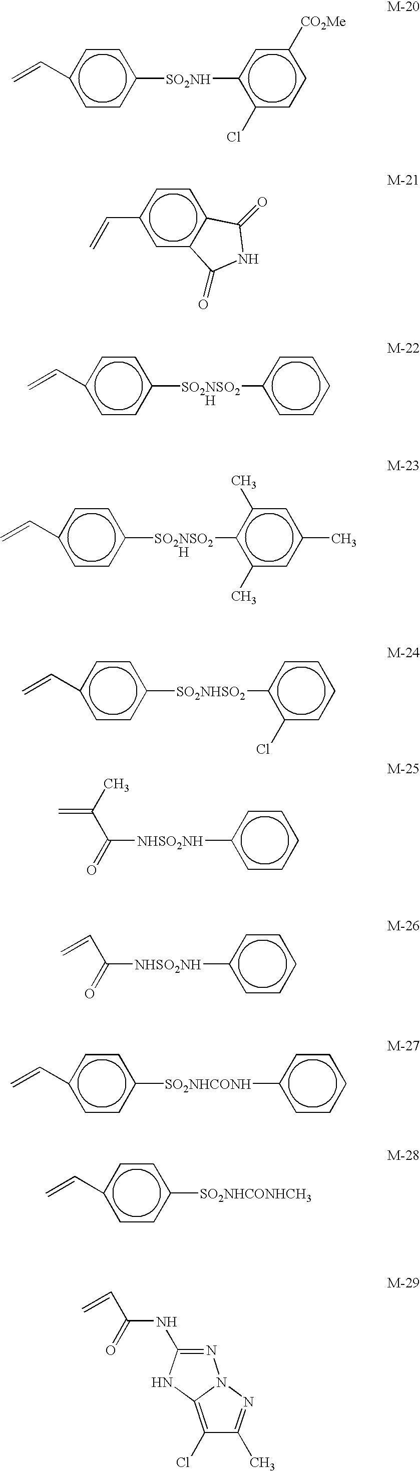

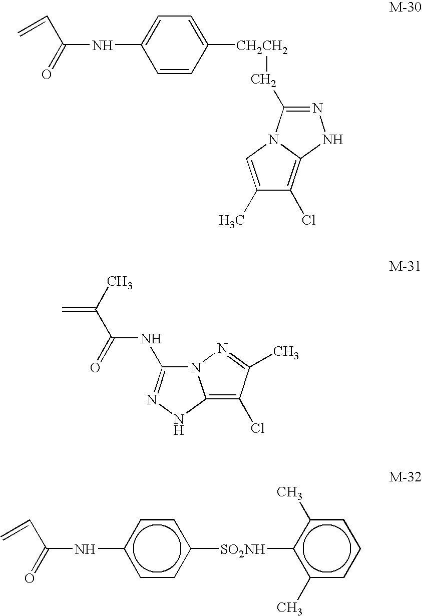

The fluorine-containing polymers (B) may be produced by a conventionally known process. For example, it may be produced by thermally polymerizing the fluoroaliphatic group-containing (meth)acrylate, the aliphatic or aromatic group-containing (meth)acrylate and the vinyl monomer having the acidic group wherein an acidic hydrogen atom is bonded to a nitrogen atom in an organic solvent by adding a conventionally used radical polymerization initiator. Alternatively, it may be produced in the same manner as described above except for further adding other addition-polymerizable unsaturated compound in some cases.

As the other addition-polymerizable unsaturated compound used in some cases, those compounds described in J. Brandrup, Polymer Handbook 2^{nd} ed., Chapter 2, pages 1 to 483, Wiley Interscience (1975) may be used.

Examples thereof include (meth)acrylates such as methyl (meth)acrylate, ethyl (meth)acrylate, 2-chloroethyl (meth)acrylate, 2-hydroxyethyl (meth)acrylate and glycidyl (meth)acrylate; (meth)acrylamides such as (meth)acrylamide, N-ethyl (meth)acrylamide, N-propyl (meth)acrylamide, N-methylol (meth)acrylamide, N,N-dimethyl (meth)acrylamide, N-hydroxyethyl (meth)acrylamide and N-(p-hydroxyphenyl) (meth)acrylamide; allyl compounds such as allyl acetate, allyl caproate and allyloxyethanol; vinyl ethers such as ethyl vinyl ether, propyl vinyl ether, butyl vinyl ether, octyl vinyl ether, methoxyethyl vinyl ether, ethoxyethyl vinyl ether, 2-chloroethyl vinyl ether, hydroxyethyl vinyl ether, benzyl vinyl ether, tetrahydrofurfuryl vinyl ether, phenyl vinyl ether, tolyl vinyl ether and diethylaminoethyl vinyl ether; vinyl esters such as vinyl acetate, vinyl butyrte, vinyl caproate, vinyl chloroacetate, vinyl methoxyacetate, vinyl phenylacetate, vinyl acetoacetate, vinyl benzoate and vinyl chlorobenzoate; styrenes such as styrene, α-methylstyrene, methylstyrene, dimethylstyrene, chloromethylstyrene, ethoxymethylstyrene, hydroxystyrene, chlorostyrene and bromostyrene; vinyl ketones sub as methyl vinyl ketone, ethyl vinyl ketone, propyl vinyl ketone and phenyl vinyl ketone; olefins such as isobutylene, butadiene and isoprene; and others such as butyl crotonate, dimethyl itaconate, diethyl itaconate, dimethyl maleate, diethyl fumarate, N-vinylpyrrolidone, N-vinylpyridine and acrylonitrile.

In addition to the monomers above, polyoxyalkylene (meth)acrylates described in JP-A-62-226143 and JP-A-3-172849 may be used. Specific examples of the fluorine-containing polymer in accordance with the invention are shown below. In the formulae, numerals attached to parentheses denote molar ratios of monomer components, respectively.

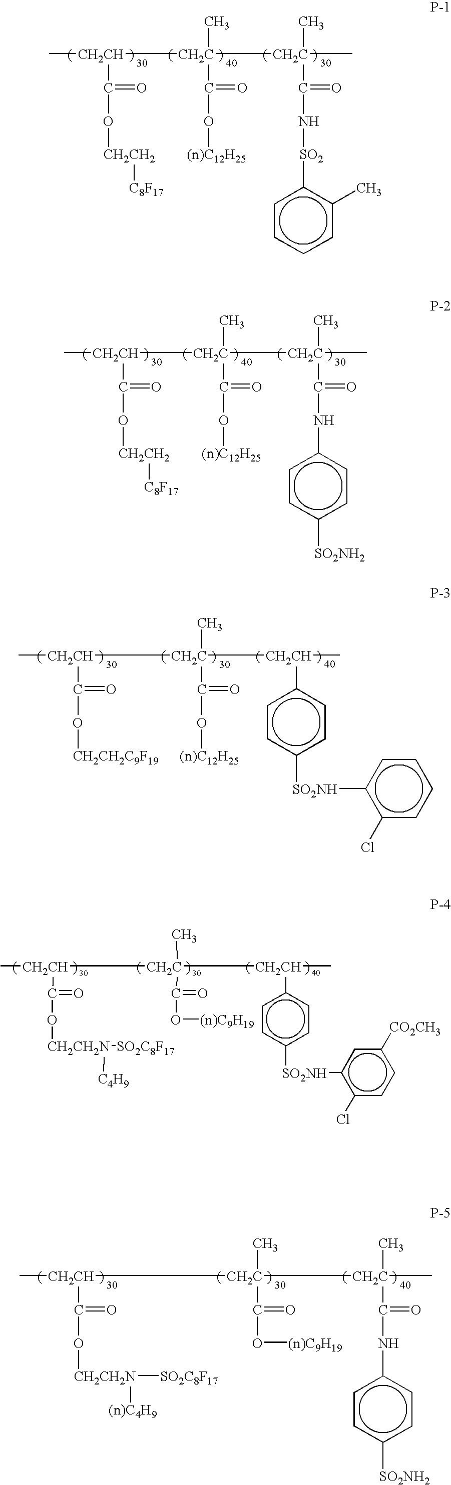

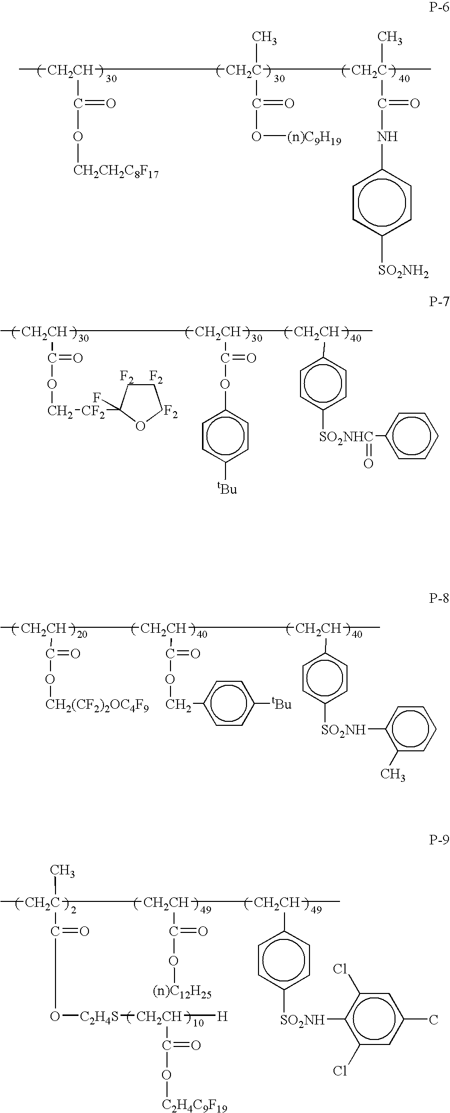

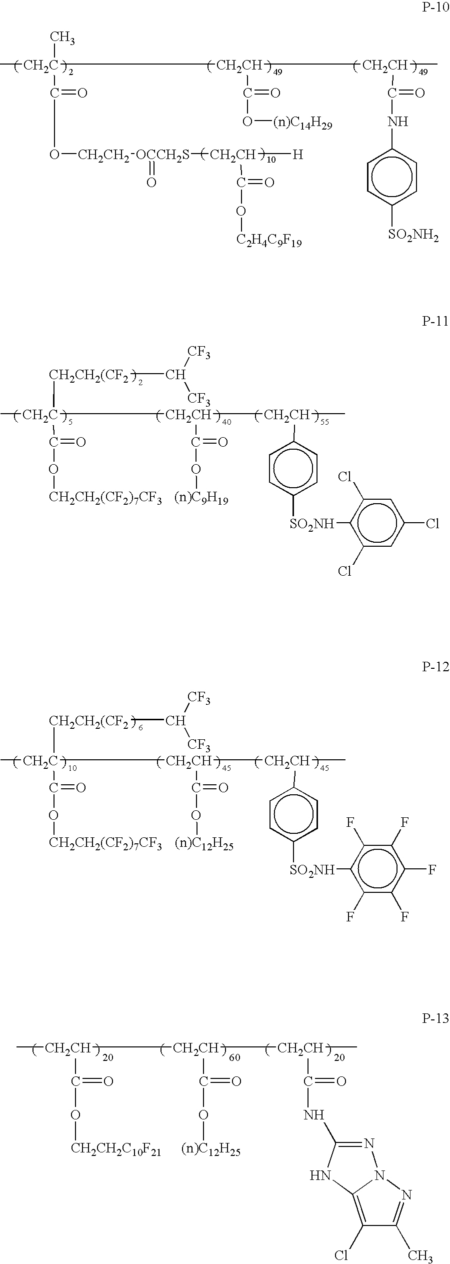

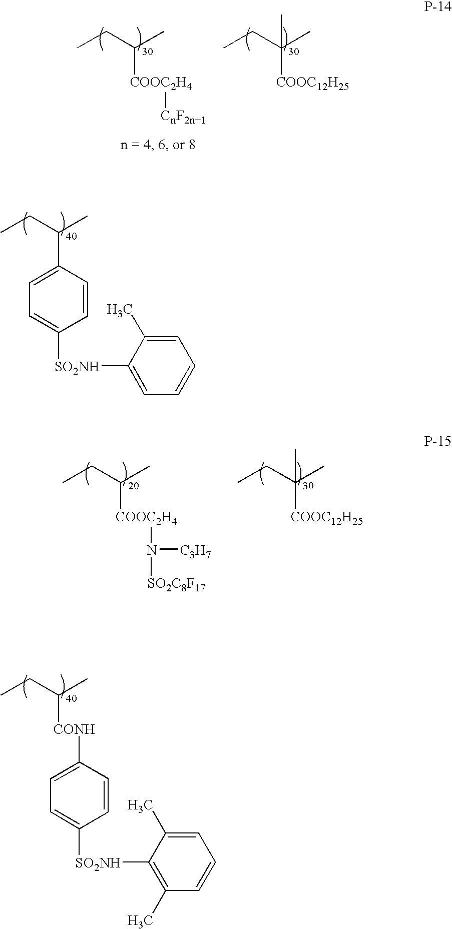

The molecular weight of the fluorine-containing polymer (B) is in a range of 3000 to 200,000, preferably 6,000 to 100,000, in terms of weight average molecular weight. The amount of the fluorine-containing polymer added is in a range of 0.001 to 10% by weight, more preferably 0.01 to 5% by weight, based on the total solid content of the heat-sensitive layer.

Now, the fluorine-containing polymer (C) (hereinafter referred to as “fluorine-containing polymer (C)”) is described in detail below.

The fluorine-containing polymer (C) is a copolymer between (i) an acrylate or methacrylate containing a fluoroaliphatic group (hereinafter referred to as “Rf group”) which contains 3 to 20 carbon atoms and 40% by weight or more fluorine atoms and in which at least 3 carbon atoms at the terminal are fully fluorinated and (ii) poly(oxyalkylene) acrylate or poly(oxyalkylene) methacrylate, with the content of the Rf group-containing acrylate or methacrylate monomer unit being 25 to 70% by weight based on the weight of the copolymer.

The fluoroaliphatic group Rf is a saturated and ordinarily monovalent aliphatic group. This is a branched chain or, in the case where it has an enough large size, a cyclic group, or a combination thereof (e.g., an alkylcycloaliphatic group). The skeletal chain of the fluoroaliphatic group may contain, in the linking chain, a hetero atom, e.g., oxygen and/or trivalent nitrogen atom bonded to only carbon atoms. The hetero atom gives a stable bond between the fluorocarbyl moieties and does not inhibit the inert property of Rf group. In order for the Rf group to exhibit its full effects, it contains 3 to 20, preferably 6 to 12, carbon atoms and 40% by weight or more, preferably 50% by weight or more, fluorine atoms bound to the carbon atoms. At least 3 carbon atoms at the terminal of the Rf group are fully fluorinated. The terminal of the Rf group is, for example, CF₃CF₂CF₂—. Preferred Rf groups are those which are substantially completely or fully fluorinated as CₙF₂ₙ₊₁ (wherein n represents an integer of 3 or more).

In case where the content of fluorine of the Rf group is less than 40% by weight, sufficient effects cannot be obtained. Larger effects result when the fluorine atoms are localized in the terminal of the Rf group. Although the fluorine content can be increased even when the Rf group contains 2 or less carbon atoms, the total number of fluorine atoms is insufficient, resulting in poor effects. Even when the fluorine content in the copolymer is increased by raising the ratio of the monomer containing the Rf group having 2 or less fully fluorinated carbon atoms to the copolymer, insufficient effects cannot be obtained because of non-localization of the fluorine atoms.

On the other hand, in case where the Rf group contains 21 or more carbon atoms, solubility of the resulting copolymer in a solvent becomes too low due to the high fluorine content, thus sufficient effects cannot be obtained.

The solubilizing moiety of the copolymer is a poly(oxyalkylene) group of (OR′)x wherein R′ preferably represents an alkylene group containing 2 to 4 carbon atoms, such as —CH₂CH₂—, —CH₂CH₂CH₂—, —CH(CH₃)CH₂— or —CH(CH₃)CH(CH₃)—. The oxyalkylene units in the poly(oxyalkylene) group may be the same as in poly(oxypropylene) or may be a mixture with an irregular distribution of two or more oxyalkylenes different from each other. The units may be straight or branched oxypropylene and oxyethyethylene, or may exist in blocks of straight or branched propylene units and oxyethylene units. The poly(oxyalkylene) chain may be interrupted by, or contain, one or more of the following chain bonds:

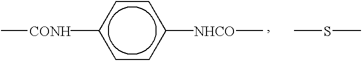

In the case where the chain bond has 3 or more valency, it provides means for obtaining branched oxyalkylene units. In order to obtain a desired solubility in the case of adding the copolymer to the heat-sensitive layer composition, the molecular weight of the poly(oxyalkylene) group is suitably 250 to 2500.

The above-mentioned copolymer may be produced by, for example, radical group initiation copolymerization between the fluoroaliphatic group-containing acrylate or fluoroaliphatic group-containing methacrylate and poly(oxyalkylene) acrylate or poly(oxyalkylene) methacrylate, such as monoacrylate, diacrylate or a mixture thereof. The molecular weight of the copolymer may be adjusted by controlling concentration and activity of an initiator, concentration of the monomers ad the polymerization reaction temperature, and by adding a chain transfer agent, for example, thiol such as n-octylmercaptan. For example, a copolymer having repeating units shown below may be obtained by copolymerizing the fluoroaliphatic group-containing acrylate, Rf—R′—O₂C—CH═CH₂ (wherein R′ represents sulfonamidoalkylene, carbonamidoalkylene or alkylene), such as C₈F₁₇SO₂N(C₄H₉)CH₂CH₂O₂CCH═CH, with the poly(oxyalkylene) monoacrylate of CH₂═CHC(O) (OR′)xOCH₃.

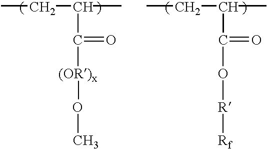

The above-mentioned fluoroaliphatic group-containing acrylates are described in U.S. Pat. Nos. 2,803,615, 2,642,416, 2,826,564, 3,102,103, 3,282,905 and 3,304,278. The poly(oxyalkylene) acrylates used for the production of the copolymer may be produced by reacting commercially available hydroxypoly(oxyalkylene) materials such as “Pluronic” (manufactured by Asahi Denka Kogyo K.K.), Adeka Polyether (manufactured by Asahi Denka Kogyo K.K.), “Carbowax” (manufactured by Glyco Products Co.), “Toriton” (manufactured by Rohm and Hass Co.) and P.E.G. (manufactured by Daiichi Kogyo Seiyaku K.K.) with acrylic acid, methacrylic acid, acryl chloride or acrylic anhydride in a known manner. Alternatively, a polyacrylate copolymer having the repeating units shown below is obtained by copolymerizing a poly(oxyalkylene) diacrylate of CH₂CHCO₂(R′O)ₓCOCH═CH₂, such as CH₂═CHCO₂(C₂H₄O)₁₀(C₃H₆O)₂₂(C₂H₄O)₁₀COCH═CH₂, with the aforementioned fluoroaliphatic group-containing acrylate.

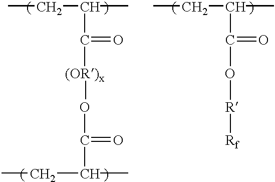

Other fluoroaliphatic group-containing unsaturated monomers having a terminal ethylenic group suitable for producing the copolymers are described in U.S. Pat. Nos. 2,592,069, 2,995,542, 3,078,245, 3,081,274, 3,291,843 and 3,325,163, and the ethylenically unsaturated materials suitable for producing the fluoroaliphatic group-containing unsaturated monomers having a terminal ethylenic group are described in U.S. Pat. No. 3,574,791.

The copolymer is a copolymer between the fluoroaliphatic group-containing acrylate or the fluoroaliphatic group-containing methacrylate and poly(oxyalkylene) acrylate or poly(oxyalkylene) methacrylate, and contains the fluoroaliphatic group-containing unit in the content of 25 to 70% by weight based on the weight of the copolymer. In case where the content of the fluoroaliphatic group-containing monomer unit is less than 25% by weight, the effects are insufficient whereas, in case where the content exceeds 70% by weight, the solubility in a solvent is too low, thus such contents not being preferred. The weight average molecular weight of the copolymer is preferably 2,500 to 100,000. In case where the molecular weight is less than 2,500, the effects are insufficient whereas, in case where the molecular weight exceeds 100,000, the solubility in a solvent is too low, thus such molecular weights not being preferred.

The copolymer is preferably a copolymer obtained by using, as the fluoroaliphatic group-containing monomer, the fluoroaliphatic group-containing acrylate in an amount of 50 to 100% by weight based on the fluoroaliphatic group-containing monomer unit and using the poly(oxyalkylene) acrylate monomer unit in an amount of 15% by weight or more based on the total amount of the copolymer, with a copolymer between the fluoroaliphatic group-containing acrylate and the poly(oxyalkylene) acrylate being particularly preferred. In case where the amount of the fluoroaliphatic group-containing methacrylate is 50% by weight or more based on the fluoroaliphatic group-containing monomer unit, the resulting copolymer exhibits decreased solubility in a solvent. In case where the amount of the poly(oxyalkylene) acrylate monomer is less than 15% by weight or less based on the total weight of the copolymer, pin-holes are liable to be formed in the resulting coating film.

The fluorine-containing polymer (C) is used in a range of preferably 0.01 to 5% by weight, more preferably 0.05 to 3% by weight, based on the total solid content of the heat-sensitive layer.

In case where the fluorine-containing polymer is used in an amount of less than 0.01% by weight, the effects are insufficient whereas, in case where used in an amount of more than 5% by weight, drying of the coating film becomes insufficient, or detrimental influences result on properties as printing plate materials (for example, developing property).

In the case of producing a positive-working lithographic printing plate precursor for use in the method of the invention, the heat-sensitive layer is provided on a support described hereinafter. The heat-sensitive layer is provided by dissolving or dispersing a composition containing necessary components in a single organic solvent or mixture of organic solvents described below.

As the organic solvent, any of known and conventionally used solvents may be used. A solvent having a boiling point of 40° C. to 200° C., particularly 60° C. to 160° C., is selected in view of advantage at the drying.

As the organic solvent, alcohols such as methyl alcohol, ethyl alcohol, n- or iso-propyl alcohol, n- or iso-butyl alcohol and diacetone alcohol; ketones such as acetone, methyl ethyl ketone, methyl propyl ketone, methyl butyl ketone, methyl amyl ketone, methyl hexyl ketone, diethyl ketone, diisobutyl ketone, cyclohexanone, methylcyclohexanone and acetylacetone; hydrocarbons such as benzene, toluene, xylene, cyclohexane and methoxybenzene; acetates such as ethyl acetate, n- or iso-propyl acetate, n- or iso-butyl acetate, ethylbutyl acetate and hexyl acetate; halogenides such as methylenedichloride, ethylenedichloride and monochlorobenzene; ethers such as isopropyl ether, n-butyl ether, dioxane, dimethyldioxane and tetrahydrofuran; polyhydric alcohols and the derivatives thereof such as ethylene glycol, methyl cellosolve, methyl cellosolve acetate, ethyl cellosolve, diethyl cellosolve, cellosolve acetate, butyl cellosolve, butyl cellosolve acetate, methoxymethoxyethanol, diethylene glycol monomethyl ether, diethylene glycol dimethyl ether, diethylene glycol methyl ethyl ether, diethylene glycol diethyl ether, propylene glycol, propylene glycol monomethyl ether, propylene glycol monomethyl ether acetate, propylene glycol monoethyl ether, propylene glycol monoethyl ether acetate, propylene glycol monobutyl ether and 3-methyl-3-methoxybutanol; and other solvents such as dimethylsulfoxide and N,N-dimethylformamide are preferably used alone or in combination thereof. The concentration of solid content in the coating composition is suitably 2 to 50% by weight.

Examples of usable methods for coating the composition for the heat-sensitive layer include a roll coating method, a dip coating method, an air-knife coating method, a gravure coating method, a gravure off-set coating method, a hopper coating method, a blade coating method, a wire doctor coating method and a spray coating method. The composition is coated in a dry amount of 0.3 to 4.0 g/m². With decreasing the coating amount, an exposure amount necessary for obtaining an image can be reduced, but the film strength is decreased. With increasing the coating amount, an exposure amount necessary for obtaining an image is increased, but the film strength is increased and, in the case of using, for example, as a printing plate, the printing plate can provide a large number of printed matters, that is the printing plate has good printing durability.

Drying of the heat-sensitive coating composition coated on the support is ordinarily conducted by heated air. The heating temperature is preferably 30° C. to 200° C., particularly preferably 40° C. to 140° C. The drying temperature may be kept at a definite level during the drying, or may be increased stepwise. Also, preferred results may be obtained in some cases by removing moisture from the drying air. The heated air is fed to the coated surface at a rate of preferably 1 m/sec to 30 m/sec, particularly preferably 0.5 m/sec to 20 m/sec.

The aluminum support used for the positive-working lithographic printing plate precursor is a dimensionally stable plate. Aluminum supports which have so far been used as supports for printing plates may preferably be used.

Such aluminum supports include a plate of pure aluminum and a plate of aluminum alloy. Various aluminum alloys such as alloys containing aluminum and a metal such as silicon, copper, manganese, magnesium, chromium, zinc, bismuth, nickel, iron or titanium may be used. The alloys also contain negligible amounts of impurities.

The aluminum support may be surface-treated, if desired. For example, it may be subjected to hydrophilicity-imparting treatment. Also, it is preferred to subject the aluminum support to a surface treatment such as graining treatment, treatment of dipping into an aqueous solution of sodium silicate, potassium fluorozirconate or phosphate, or anodic oxidation treatment. In addition, an aluminum plate having been dip-treated in an aqueous solution of sodium silicate after being grained as described in U.S. Pat. No. 2,714,066 and an aluminum plate having been dip-treated in an aqueous solution after being subjected to the anodic oxidation treatment as described in U.S. Pat. No. 3,181,461 may preferably be used.

The above-mentioned anodic oxidation treatment is conducted by applying electric current using the aluminum plate as an anode in an electrolytic solution composed of, for example, an aqueous solution or non-aqueous solution of an inorganic acid such as phosphoric acid, chromic acid, sulfuric acid or boric acid or the salt thereof or an organic acid such as oxalic acid or sulfamaic acid or the salt thereof, individually or as a mixture of two or more thereof.

Also, electrodeposition of silicate as described in U.S. Pat. No. 3,658,662 is also effective. The hydrophilicity-imparting treatment is conducted for the purpose of preventing detrimental reaction with the heat-sensitive layer to be provided thereon and for improving adhesion to the heat-sensitive layer as well as for making the support surface hydrophilic. Prior to the graining of the aluminum plate, the surface may be subjected, if desired, to a pre-treatment for removing a rolling oil on its surface or for revealing clean aluminum surface.

For the former purpose, a solvent such as trichlene or a surfactant is used. For the latter purpose, a method of using an alkali-etching agent such as sodium hydroxide or potassium hydroxide is widely employed.

As the graining method, any of mechanical, chemical and electrochemical methods are effective. As the mechanical method, there are a ball graining method, a blast graining method and a brush graining method of rubbing an aqueous dispersion slurry of an abrasive such as pumice against an aluminum support with a nylon brush. As the chemical method, a method of dipping in an aqueous solution saturated with an aluminum salt of mineral acid as described in JP-A-54-31187 is suited. As the electrochemical method, a method of conducting alternating current electrolysis in an acidic electrolytic solution of hydrochloric acid, nitric acid or a combination thereof. Of the surface-roughening methods, a roughening method of combining the mechanical surface roughening and the electrochemical surface roughening as described in JP-A-55-137993 is particularly preferred because a strong adhesion force is obtained between an ink-receptive image to the support. The graining according to the above-mentioned methods is conducted preferably in a range where the centerline roughness (Ra) of the aluminum plate surface becomes 0.3 to 1.0 μm. The thus grained aluminum plate is washed with water and chemically etched, if desired.

The etching solution is ordinarily selected from an aqueous solution of a base or acid capable of dissolving aluminum. In this case, it must be a solution which does not form on the etched surface a film different from aluminum derived from the etching component. Examples of a preferred etching agent include sodium hydroxide, potassium hydroxide, trisodium phosphate, disodium phosphate, tripotassium phosphate and disodium phosphate as basic substances; and sulfuric acid, persulfuric acid, phosphoric acid, hydrochloric acid and the salts thereof, with salts of a metal having a lower ionization tendency than aluminum, such as zinc, chromium, cobalt, nickel or copper not being preferred because they form an unnecessary film on the etched surface. Most favorably, the etching agent is used in such manner that, in the etching, the rate of dissolution of aluminum or aluminum alloy used for the support becomes 0.3 g to 40 g/m² per minute of a dipping time by appropriately selecting the concentration and temperature employed. However, the rate may exceed the upper limit or may be less than the lower limit of the range.

The etching is conducted by dipping an aluminum plate in the etching solution or by coating the etching solution on the aluminum plate preferably in such manner that the etching amount becomes within a range of 0.5 to 10 g/m². As the etching solution, an aqueous solution of the base is preferred due to its advantage of fast etching speed. In this case, smut is generated, and hence the aluminum plate is ordinarily subjected to desmutting processing. Examples of acid used in the desmutting processing include nitric acid, sulfuric acid, phosphoric acid, chromic acid, hydrofluoric acid and borofluoric acid. The etching-processed aluminum plate is, if desired, washed with water and subjected to anodic oxidation. The anodic oxidation may be conducted in a manner well conducted in this field.

Specifically, an anodic oxidation film can be formed on the surface of the aluminum support by applying direct or alternating current through aluminum in an aqueous solution or non-aqueous solution of sulfuric acid, phosphoric acid, chromic acid, oxalic acid, sulfamic acid and benzenesulfonic acid, individually or in combination of two or more thereof.

The conditions for the anodic oxidation widely vary depending upon the kind of the electrolytic solution used, and cannot be described in general but, as a general guide, conditions of 1 to 80% by weight in concentration of the electrolytic solution, 5 to 70° C. in temperature of the electrolytic solution, 0.5 to 60 A/dM² in electric current, 1 to 100 V in voltage, and 30 seconds to 50 minutes in electrolytic period of time are suitable. Of the anodic oxidation treatments, the method of conducting anodic oxidation at a high current density in sulfuric acid described in British Patent No. 1,412,768 and the method of conducting anodic oxidation using phosphoric acid as an electrolytic bath described in U.S. Pat. No. 3,511,661 are particularly preferred. The thus surface grained and anodized aluminum plate may, if desired, be subjected to hydrophilicity-imparting treatment. Preferred examples thereof include treatment using an aqueous solution of an alkali metal silicate such as sodium silicate as described in U.S. Pat. Nos. 2,714,066 and 3,181,461, treatment using potassium fluorozirconate disclosed in JP-B-36-22063 and treatment using polyvinylphosphonic acid as disclosed in U.S. Pat. No. 4,153,461.

<Organic Undercoating Layer>

It is preferred to provide an organic undercoating layer before providing the heat-sensitive layer in view of reducing the residue of the heat-sensitive layer in non-image areas. Examples of the organic compound used for such organic undercoating layer include carboxymethyl cellulose, dextrin, gum arabic, amino group-containing phosphonic acids such as 2-aminoethylphosphonic acid, optionally substituted organic phosphonic acids such as phenylphosphonic acid, naphthylphosphonic acid, alkylphosphonic acid, glycerophosphonic acid, methylenediphosphonic acid and ethylenediphosphonic acid, optionally substituted organic phosphoric acids such as phenylphosphoric acid, naphthylphosphoric acid, alkylphosphoric acid and glycerophosphoric acid, optionally substituted organic phosphinic acids such as phenylphosphinic acid, naphthylphosphinic acid, alkylphosphinic acid and glycerophosphinic acid, amino acids such as glycine and β-alanine, and hydroxyl group-containing amine hydrochlorides such as triethanolamine hydrochloride. The organic compounds may be used in combination of two or more thereof.

In addition, at least one compound selected from high-molecular compounds having a structural unit typified by poly(p-vinylbenzoic acid) in its molecule may be used. More specifically, there are illustrated a copolymer between p-vinylbenzoic acid and vinylbenzyltrimethylammonium salt and a copolymer between p-vinylbenzoic acid and vinylbenzyltrimethylammonium chloride.

The organic undercoating layer may be provided according to the following manner. Specifically, the organic undercoating layer may be provided by a method of coating a solution of the above-described organic compound dissolved in water or an organic solvent such as methanol, ethanol or methyl ethyl ketone or a mixed solvent thereof on an aluminum plate, followed by drying, or a method of dipping an aluminum plate in a solution of the above-described organic compound dissolved in water or an organic solvent such as methanol, ethanol or methyl ethyl ketone or a mixed solvent thereof to adsorb the organic compound, followed by washing with water and drying. In the former method, a 0.005 to 10% by weight solution of the organic compound may be coated according to various methods. For example, any of bar coater coating, rotary coating, spray coating and curtain coating may be employed. In the latter method, the concentration of the organic compound in the solution is 0.01 to 20% by weight, preferably 0.05 to 5% by weight, the dipping temperature is 20 to 90° C., preferably 25 to 50° C., and the dipping period of time is 0.1 second to 20 minutes, preferably 2 seconds to 1 minute.

The pH of the solution used may be adjusted in the range of 1 to 12 using a basic substance such as ammonia, triethylamine or potassium hydroxide or an acidic substance such as hydrochloric acid or phosphoric acid. Also, a yellow dye may be added for improving tone reproducibility of a lithographic printing plate precursor. Further, to the solution may be added a compound represented by the following formula (f):

(HO)ₓ—R⁵—(COOH)_{y} (f)

wherein R⁵ represents an optionally substituted arylene group having 14 or less carbon atoms, and x and y each independently represents an integer of 1 to 3. Specific examples of the compound represented by the formula (f) include 3-hydroxybenzoic acid, 4-hydroxybenzoic acid, salicylic acid, 1-hydroxy-2-naphthoic acid, 2-hydroxy-1-naphthoic acid, 2-hydroxy-3-naphthoic acid, 2,4-dihydroxybenzoic acid and 10-hydroxy-9-anthracenecarboxylic acid. The dry coating amount of the organic undercoating layer is suitably 1 to 100 mg/m², preferably 2 to 70 mg/m². In case where the coating amount is less than 2 mg/m², a sufficient printing durability cannot be obtained. In case where the coating amount is more than 100 mg/m², also a sufficient printing durability cannot be obtained.

<Back Coating Layer>

A back coating layer is provided on the back side of the support, if desired. As such a back coating layer, a coating layer comprising an organic high-molecular compound described in JP-A-5-45885 or a coating layer comprising a metal oxide obtained by hydrolysis and polycondensation of an organic or inorganic metal compound described in JP-A-6-35174 is preferably used. Of the coating layers, a coating layer comprising a metal oxide obtained from alkoxy compound of silicon such as Si(OCH₃)₄, Si(OC₂H₅)₄, Si(OC₃H₇)₄ and Si(OC₄H₉)₄ which is inexpensive and easily available has an excellent resistance against a developing solution, thus being particularly preferred.

The lithographic printing plate precursor thus-prepared is usually subjected to imagewise exposure and development processing. As a light source of active ray used for the imagewise exposure, a light source having an emitting wavelength of a near-infrared to infrared region is preferred. A solid-state laser and a semiconductor laser are particularly preferred.

A preferred developing solution used for the plate-making method of the invention for making a lithographic printing plate is a developing solution containing (a) at least one compound selected from non-reducing sugars and (b) at least one base, and having a pH in a range of 9.0 to 13.5. Such a developing solution is described in detail below. In the specification, the term “developing solution” means a development-initiating solution (developing solution in a narrow sense) and a development replenisher unless otherwise indicated.

The developing solution mainly comprises at least one compound selected from non-reducing sugars and at least one base, and has a pH in a range of preferably 9.0 to 13.5. Such non-reducing sugars include sugars which do not have any free aldehyde group and ketone group and do not show reducing properties. They are classified into trehalose type oligosaccharides wherein reducing groups are bonded to each other, glycosides wherein a reducing group of a sugar is bonded to a non-sugar compound, and sugar alcohols which are obtained by hydrogenation of sugars, and any type of reducing sugars are preferably used. The trehalose type oligosaccharides include saccharose and trehalose, the glycosides include alkyl glycosides, phenol glycosides and mustard oil glycosides, and the sugar alcohols include D,L-arabitol, ribitol, xylytol, D,L-sorbitol, D,L-mannitol, D,L-iditol, D,L-talitol, dulcitol and allodulcitol. Further, maltitol obtained by hydrogenation of disaccharide and a reduced product (reduced starch syrup) obtained by hydrogenation of oligosaccharides may preferably be used.

Of the non-reducing sugars, sugar alcohols and saccharose are preferred, and D-sorbitol, saccharose and reduced starch syrup are particularly preferred since they have a buffering action in a suitable pH region and are inexpensive.

The non-reducing sugars may be used alone or in combination of two or more thereof. The content of the non-reducing sugar in the developing solution is preferably 0.1 to 30% by weight, more preferably 1 to 20% by weight.

In case where the content is less than the range, a sufficient buffering effect cannot be obtained whereas, in case where the content exceeds the range, it becomes difficult to attain a high concentration, and a problem of an increase in material cost arises.

On the contrary, when a reducing sugar is used in combination with a base, problems arise in that the resulting solution becomes brown and that pH of the solution decreases gradually with the lapse of time, thus developing properties being deteriorated.

As the base used in combination with the non-reducing sugar, conventionally known alkali agents may be used. Examples thereof include inorganic alkali agents such as sodium hydroxide, potassium hydroxide, lithium hydroxide, trisodium phosphate, tripotassium phosphate, triammonium phosphate, disodium phosphate, dipotassium phosphate, diammonium phosphate, sodium carbonate, potassium carbonate, ammonium carbonate, sodium hydrogen carbonate, potassium hydrogen carbonate, ammonium hydrogen carbonate, sodium borate, potassium borate and ammonium borate. Also, organic alkali agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine and pyridine may be used.

The alkali agents may be used alone or in combination of two or more thereof. Of these, sodium hydroxide and potassium hydroxide are preferred, because they permit adjustment of pH over a wide pH range by adjusting the amount thereof relative to the amount of the non-reducing sugar. Also, trisodium phosphate, tripotassium phosphate, sodium carbonate and potassium carbonate are preferred due to their own buffering action.

The alkali agent is added so as to adjust pH of the developing solution to a range of 9.0 to 13.5. The addition amount thereof is determined based on desired pH and the kind and amount of the non-reducing sugar. A more preferred range of the pH is 10.0 to 13.2.

In the developing solution may further be used an alkaline buffer solution comprising a weak acid other than the sugars and a strong base. As the weak acid used in such buffer solution, acids having a dissociation constant (pKa) of 10.0 to 13.2 are preferred.

The weak acid is selected from those described in, for example, IONIZATION CONSTANTS OF ORGANIC ACIDS IN AQUEOUS SOLUTION published by Pergamon Press. Examples thereof include alcohols such as 2,2,3,3-tetrafluoropropanol-1 (pKa 12.74), trifluoroethanol (pKa 12.37) and trichloroethanol (pKa 12.24); aldehydes such as pyridine-2-aldehyde (pKa 12.68) and pyridine-4-aldehyde (pKa 12.05); phenolic hydroxy group-containing compounds such as salicylic acid (pKa 13.0), 3-hydroxy-2-naphthoic acid (pKa 12.84), catechol (pKa 12.6), gallic acid (pKa 12.4), sulfosalicylic acid (pKa 11.7), 3,4-dihydroxysulfonic acid (pKa 12.2), 3,4-dihydroxybenzoic acid (pKa 11.94), 1,2,4-trihydroxybenzene (pKa 11.82), hydroquinone (pKa 11.56), pyrogallol (pKa 11.34), o-cresol (pKa 10.33), resorcinol (pKa 11.27), p-cresol (pKa 10.27) and m-cresol (pKa 10.09); oximes such as 2-butanone oxime, (pKa 12.45), acetoxime (pKa 12.42), 1,2-cycloheptanedione dioxime (pKa 12.3), 2-hydroxybenzaldehyde oxime (pKa 12.10), dimethylglyoxime (pKa 11.9), ethanediamide dioxime (pKa 11.37) and acetophenone oxime (pKa 11.35); nucleic acid-related substances such as adenosine (pKa 12.56), inosine (pKa 12.5), guanine (pKa 12.3), cytosine (pKa 12.2), hypoxanthine (pKa12.1) and xanthine (pKa 11.9); and others such as diethylaminomethylphosphonic acid (pKa 12.32), 1-amino-3,3,3-trifluorobenzoic acid (pKa 12.29), isopropylydenediphosphonic acid (pKa 12.10), 1,1-ethylydenediphosphonic acid (pKa 11.54), 1,1-ethylydenediphosphonic acid-1-hydroxy (pKa 11.52), benzimidazole (pKa 12.86), thiobenzamide (pKa 12.8), picolinethioamide (pKa 12.55) and barbituric acid (pKa 12.5).

Of the weak acids, sulfosalicylic acid and salicylic acid are preferred. As the base used in combination with the weak acid, sodium hydroxide, ammonium hydroxide, potassium hydroxide and lithium hydroxide are preferably used. The alkali agents are used alone or in combination of two or more thereof. The above-mentioned various alkali agents are used in such amount and combination that the pH falls within the preferred range.

To the developing solution may be added various surfactants or organic solvents, if desired, for the purpose of accelerating development and dispersing development scum and for enhancing ink affinity of the image area of printing plate. Preferred examples of the surfactant include anionic, cationic, nonionic and amphoteric surfactants.

Preferred surfactants include nonionic surfactants such as polyoxyethylene alkyl ethers, polyoxyethylene alkylphenyl ethers, polyoxyethylene polystyrylphenyl ethers, polyoxyethylenepolyoxypropylene alkyl ethers, partial esters of glycerol with fatty acid, partial esters of sorbitan with fatty acid, partial esters of pentaerythritol with fatty acid, propylene glycol monoester with fatty acid, partial esters of sugar with fatty acid, partial esters of polyoxyethylenesorbitan with fatty acid, partial esters of polyoxyethylenesorbitol with fatty acid, polyethylene glycol esters with fatty acid, partial esters of polyglycerin with fatty acid, polyoxyethylenated castor oil, partial estsers of polyoxyethyleneglycerin with fatty acid, fatty acid diethanolamides, N,N-bis-2-hydroxyalkylamines, polyoxyethylenealkylamines, triethanolamine fatty acid esters and trialkylamine oxides; anionic surfactants such as fatty acid salts, abietic acid salts, hydroxyalkanesulfonic acid salts, alkanesulfonic acid salts, dialkylsullfosucccinic acid ester salts, straight alkylbenzenesulfonic acid salts, branched alkylbenzenesulfonic acid salts, alkylnaphthalenesulfonic acid salts, alkylphenoxypolyoxyethylenepropylsulfonic acid salts, polyoxyethylene alkylsulfophenyl ether salts, N-methyl-N-oleyltaurine sodium salt, N-alkylsulfosuccinic acid monoamide disodium salt, petroleum sulfonic acid salts, sulfated tallow oil, sulfuric ester salts of fatty acid alkyl esters, alkylsulfuric ester salts, polyoxyethylene alkyl ether sulfuric ester salts, fatty acid monoglyceride sulfuric ester salts, polyoxyethylene alkylphenyl ether sulfuric ester salts, polyoxyethylene styrylphenyl ether sulfuric ester salts, alkylphosphoric acid ester salts, polyoxyethylene alkyl ether phosphoric ester salts, polyoxyethylene alkylphenyl ether phosphoric ester salts, partially saponified products of styrene/maleic anhydride copolymers, partially saponified products of olefin/maleic anhydride copolymers and naphthalenesulfonic acid salt formalin condensates; cationic surfactants such as alkylamines, quaternary ammonium salts (e.g., tetrabutylammonium bromide), polyoxyethylenealkylamine salts and polyethylenepolyamine derivatives; and amphoteric surfactants such as carboxybetaines, aminocarboxylic acids, sulfobetaines, aminosulfuric esters and imidazolines. In the above-illustrated surfactants, the term “polyoxyethylene” may be replaced by polyoxyalkylene such as polyoxymethylene, polyoxypropylene or polyoxybutylene, and such surfactants are also included.

More preferred surfactants include fluorine-containing surfactants including a perfluoroalkyl group in the molecules thereof. Examples of the fluorine-containing surfactant include anionic surfactants such as perfluoroalkylcarboxylic acid salts, perfluoroalkylsulfonic acid salts and perfluoroalkylphosphoric acid esters; amphoteric surfactants such as perfluoroalkylbetaines; cationic surfactants such as perfluoroalkyltrimethylammonium salts; and nonionic surfactants such as perfluoroalkylamine oxides, ethylene oxide adducts of perfluoroalkyl, oligomers containing a perfluoroalkyl group and a hydrophilic group, oligomers containing a perfluoroalkyl group and an oleophilic group, oligomers containing a perfluoroalkyl group, a hydrophilic group and an oleophilic group, and urethane containing a perfluoroalkyl group and an oleophilic group. The surfactants may be used alone or in combination of two or more thereof. The amount of surfactant added to the developing solution is preferably in a range of 0.001 to 10% by weight, more preferably 0.01 to 5% by weight.

To the developing solution may be added various development-stabilizing agents. Preferred examples thereof include polyethylene glycol adducts of sugar alcohols described in JP-A-6-282079, tetraalkylammonium salts such as tetrabutylammonium hydroxide, phosphonium salts such as tetrabutylphosphonium salt, and iodonium salts such as diphenyliodonium chloride. Further, there are illustrated anionic surfactants or amphoteric surfactants described in JP-A-50-51324, water-soluble cationic polymers described in JP-A-55-95946 and water-soluble amphoteric high-molecular electrolytes described in JP-A-56-142528.

Still further, alkylene glycol-added organic boron compounds described in JP-A-59-84241, polyoxyethylene-polyoxypropylene block polymer type water-soluble surfactants described in JP-A-60-111246, polyoxyethylene-polyoxypropylene-substituted alkylenediamine compounds described in JP-A-60-129750, polyethylene glycol having a weight-average molecular weight of 300 or more described in JP-A-61-215554, cationic group-having, fluorine-containing surfactants described in JP-A-63-175858, water-soluble ethylene oxide adduct compounds obtained by adding 4 moles or more ethylene oxide to an acid or alcohol described in JP-A-2-39157, and water-soluble polyalkylene compounds.

To the developing solution may be added, if desired, an organic solvent. As such an organic solvent, an organic solvent having solubility in water of about 10% by weight or less is suitable, and an organic solvent have the solubility of 5% by weight or less is preferably selected. Examples thereof include 1-phenylethanol, 2-phenylethanol, 3-phenyl-1-propanol, 4-phenyl-1-butanol, 4-phenyl-2-butnol, 2-phenyl-1-butnol, 2-phenoxyethanol, 2-benzyloxyethanol, o-methoxybenzyl alcohol, m-methoxybenzyl alcohol, p-methoxybenzyl alcohol, benzyl alcohol, cyclohexanol, 2-methylcyclohexanol, 3-methylcyclohexanol, 4-methylcyclohexanol, N-phenylethanolamine and phenyldiethanolamine.

The content of the organic solvent is 1 to 5% by weight based on the total weight of the developing solution used. The amount is closely related to the amount of the surfactant used and, as the amount of the organic solvent increases, the amount of the surfactant is preferably increased. This is because, in case when the amount of the surfactant is small and the amount of the organic solvent is large, the organic solvent does not completely dissolve, thus good developing property cannot be expected.

Still further, a reducing agent may be added to the developing solution. The addition of reducing agent is for preventing a printing plate from staining, and is particularly effective upon developing a lithographic printing plate precursor containing a light-sensitive diazonium salt compound. Preferred examples of the reducing agent include thiosalicylic acid, phenolic compounds such as hydroquinone, Metol, methoxyquinone, resorcinol and 2-methylresorcinol, and amine compounds such as phenylenediamine and phenylhydrazine. Further, preferred examples of inorganic reducing agents include sodium salts, potassium salts and ammonium salts of inorganic acids such as sulfurous acid, hydrogen sulfurous acid, phosphorous acid, dihydrogenphosphorous acid, thiosulfuric acid and dithiosulfurous acid. Of the reducing agents, sulfites show the particularly excellent stain-preventing effect. The reducing agent is contained in an amount of preferably 0.05 to 5% by weight based on the developing solution upon use.

To the developing solution may further be added an organic carboxylic acid. Preferred organic carboxylic acids include aliphatic carboxylic acids containing 6 to 20 carbon atoms and aromatic carboxylic acids. Specific examples of the aliphatic carboxylic acid include caproic acid, enanthylic acid, capric acid, lauric acid, myristic acid, palmitic acid and stearic acid. Alkanoic acids containing 8 to 12 carbon atoms are particularly preferred. Unsaturated fatty acids containing a double bond in the carbon chain and those containing a branched carbon chain may also be used. The aromatic carboxylic acids include compounds wherein a carboxyl group is bonded to a benzene ring, a naphthalene ring or an anthracene ring. Specific examples thereof include o-chlorobenzoic acid, p-chlorobenzoic acid, o-hydroxybenzoic acid, p-hydroxybenzoic acid, o-aminobenzoic acid, p-aminobenzoic acid, 2,4-dihydroxybenzoic acid, 2,5-dihydroxybenzoic acid, 2,6-dihydroxybenzoic acid, 2,3-dihydroxybenzoic acid, 3,5-dihydroxybenzoic acid, gallic acid, 1-hydroxy-2-naphthoic acid, 3-hydroxy-2-naphthoic acid, 2-hydroxy-1-naphthoic acid, 1-naphthoic acid and 2-naphthoic acid. Hydroxynaphthoic acid is particularly effective.

The aliphatic and aromatic carboxylic acids are used preferably as sodium salts, potassium salts or ammonium salts for enhancing solubility in water. The content of the organic carboxylic acid in the developing solution for use in the invention is not particularly limited. However, in case where the content is less than 0.1% by weight, insufficient effects are not obtained whereas, in case where the content exceeds 10% by weight, there are obtained no more effects and, in addition, in some cases the organic acid may inhibit dissolution of other additive, if any. Therefore, a preferred addition amount is 0.1 to 10% by weight, more preferably 0.5 to 4% by weight, based on the weight of the developing solution upon use.

To the developing solution may further be added, if desired, an antiseptic, a colorant, a thickening agent, defoaming agent and a water softener. Examples of the water softener include polyphosphoric acid and the sodium salt, potassium salt and ammonium salt thereof; aminopolycarboxylic acids such as ethylenediaminetetraacetic acid, diethylenetriaminepentaacetic acid, triethylenetetraminehexaacetic acid, hydroxyethylethylenediaminetriacetic acid, nitrilotriacetic acid, 1,2-diaminocyclohexanetetraacetic acid and 1,3-diamino-2-propanoltetraacetic acid and the sodium salts, potassium salts and ammonium salts thereof; and aminotri(methylenephosphonic acid), ethylenediaminetetra(methylenephosphonic acid), diethylenetriaminepenta(methylenephosphonic acid), triethylenetetraminehexa(methylenephosphonic acid), hydroxyethylethylenediaminetri(methylenephosphonic acid) and 1-hydroxyethane-1,1-diphosphonic acid, and the sodium salts, potassium salts and ammonium salts thereof.

The optimum amount of such water softener varies depending upon its chelating ability and hardness and amount of hard water but, as a general guide, it is in a range of 0.01 to 5% by weight, more preferably 0.01 to 0.5% by weight. In case where the addition amount is less than the range, the intended object cannot be fully attained whereas, in case where the amount exceeds the range, there result detrimental influences on the image areas such as coloring loss. The rest component of the developing solution is water. In view of transportation, it is advantageous to prepare it as a concentrate containing less amount of water than upon use and, upon use, dilute with water. The concentration degree of the concentrate is suitably such that each component does not cause separation or precipitation.

As the developing solution for use in the method for making a lithographic printing plate according to the invention, the developer described in JP-A-6-282079may also be used. The developing solution contains an alkali metal silicate having a molar ratio of SiO₂/M₂O (wherein M represents an alkali metal) of 0.5 to 2.0 and a water-soluble ethylene oxide adduct obtained by adding 5 moles or more of ethylene oxide to a sugar alcohol having 4 or more hydroxyl groups. The sugar alcohol is a polyhydric alcohol corresponding to that obtained by reducing an aldehyde group or ketone group of a sugar to a primary alcohol group or secondary alcohol group. Specific examples of the sugar alcohol include D,L-threitol, erythritol, D,L-arabitol, ribitol, xylitol, D,L-sorbitol, D,L-mannitol, D,L-iditol, talitol, dulcitol and allodulcitol and, further, include di-, tri-, tetra-, penta- and hexa-glycerin obtained by condensing the sugar alcohol. The above-mentioned water-soluble ethylene oxide adducts are obtained by adding 5 moles or more ethylene oxide to 1 mole of the sugar alcohols. Further, the ethylene oxide adduct may, if desired, contain propylene oxide block-copolymerized within a range acceptable for the solubility. The ethylene oxide adducts may be used independently or in combination of two or more thereof.

The amount of the water-soluble ethylene oxide adduct added is suitably 0.001 to 5% by weight, preferably 0.001 to 2% by weight, based on the weight of the developing solution (for use).

To the developing solution may further be added, if desired, the aforementioned various surfactants and organic solvents for the purpose of dispersing development dust and enhancing ink affinity of the image area of printing plate.

The PS plate having been subjected to development processing with the developing solution is then subjected to post-treatment with washing water, a rinsing solution containing a surfactant, or the aforementioned finishing gum solution.

The lithographic printing plate obtained by the method of the invention is mounted on an offset printing machine to produce a large number of printed products.

The invention will be described in more detail by reference to the following examples, however, the invention should not be construed as being limited thereto.

<Preparation of Support [A]>

Molten metal was prepared using an aluminum alloy containing 0.06% by weight of Si, 0.30% by weight of Fe, 0.005% by weight of Cu, 0.001% by weight of Mn, 0.001% by weight of Mg, 0.001% by weight of Zn and 0.03% by weight of Ti and balance of Al and unavoidable impurities, subjected to molten metal treatment and filtration, and made into an ingot of 500 mm in thickness and 1200 mm in width according to the DC casting method. After cutting the surface to a depth of 10 mm on the average using a planer, the ingot was uniformly kept at 550° C. for about 5 hours and, when the temperature of the ingot decreased to 400° C., it was rolled into a 2.7-mm thick rolled plate using a hot rolling machine. Further, it was subjected to thermal treatment at 500° C. using a continuous annealing machine, then finished into a 0.30-mm thick plate by cold rolling to obtain an aluminum plate of JIS 1050 material. The aluminum plate was cut into pieces of 1030 mm in width, and was then subjected to the following surface treatment.

A support was prepared by subjecting the above-mentioned aluminum plate to the following surface treatment.

[Method for Preparing Support A]

Support A was prepared by continuously subjecting the aluminum plate to the following surface-treating steps (a) to (h) in order. Each of the treatments and washings was followed by removing the liquid by means of nip rollers.

[a] Mechanically Surface-Roughening Treatment

Mechanical roughening of the plate was conducted by means of a rotating roller-form nylon brush while feeding an aqueous suspension of an abrasive (pumice) in water having 1.12 in specific gravity in water as an abrasion slurry solution to the surface of the aluminum plate. Average particle size of the abrasive was 40 μm, with the maximum particle size being 100 μm. The nylon brush was made of 6·10 nylon, and was 50 mm in brush bristle length and 0.3 mm in brush bristle diameter. The nylon brush was made by making holes in a stainless steel-made cylinder of 300 mm in diameter and densely filling the brush bristles. Three of the rotating brushes were used. Two supporting rollers (200 mm in diameter) provided under the brushes were spaced 300 mm. The brush rollers were pressed against the aluminum plate till the load applied to a driving motor for rotating the brush became 7 kg greater than the load before pressing the brush rollers against the aluminum plate.

The rotating direction of the brushes was the same as the moving direction of the aluminum plate. The rotation number of the brushes was 250 rpm, and the surface roughness (Ra) of the resultant support was 0.55 μm.

[b] Alkali-Etching Treatment

Etching processing was conducted by spraying a NaOH aqueous solution of 2.6% by weight in concentration, 6.5% by weight in aluminum ion concentration and 72° C. in temperature to dissolve the aluminum plate to a degree of 10 g/m², followed by washing with water by spraying.

[c] Desmut Processing

Desmut treatment was conducted by spraying an aqueous solution of 30° C. in temperature and 10.4 g/liter in nitric acid concentration (containing 4.5 g/liter of aluminum ion), followed by washing with water by spraying. The nitric acid aqueous solution used for the desmut treatment was a waste liquor from the step of conducting electrochemically surface-roughening treatment in an aqueous nitric acid solution using alternating current described below.

[d] Electrochemically Surface-Roughening Treatment

Electrochemically surface-roughening treatment was continuously conducted by applying a 60 Hz alternating current voltage. The electrolytic solution used was an aqueous solution of50° C. in solution temperature containing 10.4 g/liter of nitric cid (containing 4.5 g/liter of aluminum ion and 0.007% by weight of ammonium ion). The electrochemically surface-roughening treatment was conducted using an alternating current source which provides a trapezoidal rectangular wave alternating current of 0.8 msec in time TP for the current to reach its peak from zero and 1:1 in duty ratio and using a carbon electrode as a counter electrode. A ferrite was used as an auxiliary anode.

The electric current density was 30 A/dm² at the peak current, and the electric amount was 220 C/dm² in terms of the total electric amount during the aluminum plate functioning as an anode. 5% of the current from the electric source was provided to the auxiliary anode. Subsequently, washing with water was conducted by spraying.

[e] Alkali-Etching Treatment

Etching treatment was conducted at 61° C. by spraying an aqueous solution of 2.6% by weight in concentration of sodium hydroxide and 6.5% by weight in aluminum ion concentration to dissolve the aluminum plate in an amount of 0.9 g/m². Thus, the smut component generated in the foregoing electrochemically surface-roughening treatment mainly comprising aluminum hydroxide and edge portion of the bit were dissolved away to smoothen the edge portion. Subsequently, washing with water was conducted by spraying.

[f] Desmut Treatment

Desmut treatment was conducted by spraying an aqueous solution of 30° C. in temperature and 170 g/liter in sulfuric acid concentration (containing 4.5 g/liter of aluminum ion), followed by washing with water by spraying. The sulfuric acid aqueous solution used for the desmut treatment was a waste liquor from the step of conducting anodizing treatment in a sulfuric acid aqueous solution described below.

[g] Anodizing Treatment

A sulfuric acid solution was used as the electrolytic solution. The electrolytic solution was 170 g/liter in sulfuric acid concentration (containing 0.5% by weight of aluminum ion) and 43° C. in temperature. Subsequently, washing with water was conducted by spraying. The final oxide film amount was 2.5 g/m².

[h] Hydrophilicity-Imparting Treatment

Hydrophilicity-imparting treatment (treatment with alkali silicate) was conducted by immersing in a processing tank containing a 1% by weight aqueous solution of No.3 sodium silicate of 30° C. for 10 seconds.

(Method for Preparing Support [(B])

Support B was prepared by continuously conducting steps [b] to [h] of the above-mentioned surface-treating steps provided that, in step [b], the solution temperature was changed to 68° C. to dissolve 5.5 g/m² of aluminum and, in step [e], the solution temperature was changed to 38° C. to dissolve 0.25 g/m² of aluminum.

Each of the treatments and washings was followed by removing the liquid by means of nip rollers.

<Back Coat>

Next, the following diluted sol-gel reaction solution was coated on the back surface of each of support [A] and support [B] using a bar coater, followed by drying at 100° C. for 1 minute to provide a back coat layer of 60 mg/m² in dry coated amount.

Sol-gel reaction solution:

| | |
|---|---|
| Tetraethyl silicate | 50.0 parts by weight |
| Water | 86.4 parts by weight |
| Methanol | 10.8 parts by weight |
| Phosphoric acid (85%) | 0.08 parts by weight |

When the above-mentioned components were mixed and stirred, the mixture generated heat in about 35 minutes. After stirring for 40 minutes to react, the reaction mixture was mixed with the following diluting solution to prepare a back coat-coating solution.

Diluting Solution:

| | |
|---|---|
| Pyrogallol-acetone | 15.0 parts by weight |
| condensate resin | |
| Dibutyl maleate | 5.0 parts by weight |
| Methanol-silica sol (made by | 70.0 parts by weight |
| Nissan Chemical Indurtries, Ltd.) | |
| Megafac F-117 (made by | 0.1 part by weight |
| Dainippon Ink and Chemicals, Inc.) | |
| Methanol | 650 parts by weight |
| 1-Methoxy-2-propanol | 200 parts by weight |

<Organic Interlayer>

Next, an organic interlayer-coating solution of the following formulation was coated on the surface subjected to the surface treatment of each of support [A] and support [B] having provided on the back side thereof the back coat layer, using a bar coater, followed by drying at 100° C. for 10 seconds to provide an organic interlayer. The dry coated amount of the organic interlayer was 15 mg/m².

Formulation of the Organic Interlayer-Coating Solution:

| | | |
|---|---|---|
| Compound A shown below | 0.2 | parts by weight |
| Methanol | 100 | parts by weight |
| Water | 1.0 | part by weight |

Compound A

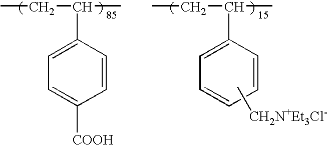

molecular weight: 28,000
note)
Numerals denote mol %.

<Formation of Heat-Sensitive Layer>

Next, the following coating solution was coated on the surface of the organic interlayer provided on each of the support [A] and support [B] (on the organic interlayer side) using a bar coater, followed by drying at 140° C. for 60 seconds to obtain lithographic printing plate precursors. The dry coated amount of the coating solution was 1.1 g/m².

Coating solution:

| | |
|---|---|
| Fluorine-containing polymer C-1 | 0.02 parts by weight |
| described below | |
| Fluorine-containing polymer D-1 | 0.04 parts by weight |
| described below | |
| Fluorine-containing polymer E-1 | 0.002 parts by weight |
| described below | |
| Specific copolyrner 1 | 2.00 parts by weight |
| described below | |
| m,p-Cresol novolak (m/p ratio = | 0.50 parts by weight |
| 6/4; weight-average molecular | |
| weight: 3,500; content of | |
| unreacted cresol: 0.5% by weight) | |
| p-Toluenesulfonic acid | 0.01 part by weight |
| Tetrahydroxyphthalic anhydride | 0.20 parts by weight |
| Bishydroxyphenylsulfone | 0.15 parts by weight |
| 3-Methoxy-4-diazodiphenylamine | 0.03 parts by weight |
| Cyanine dye A shown below | 0.17 parts by weight |
| Additive B shown below | 0.02 parts by weight |
| Additive C shown below | 0.04 parts by weight |
| Dye obtained by replacing counter | 0.10 parts by weight |
| ion of Victoria Pure Blue BOH by | |
| 1-naphthalenesulfonate anion | |
| γ-Butyrolactone | 10 parts by weight |
| Methyl ethyl ketone | 20 parts by weight |
| 1-Methoxy-2-propanol | 10 parts by weight |

Synthesis of the Fluorine-Containing Polymer C-1

117 g of methyl isobutyl ketone was placed in a 500-ml 3-necked flask equipped with a stirrer, a condenser and a dropping funnel and was heated to 75° C. in a hot water bath, and a mixture of 36.0 g of fluorine-containing monomer (A-31) described hereinbefore, 12.0 g of 2-hydroxyethyl methacrylate, 25.0 g of methyl methacrylate, 27.0 g of compound (I) shown below, 117 g of methyl isobutyl ketone, and 1.15 g of V-601 (made by Wako Pure Chemical industries, Ltd.) was added thereto for 2 hours through the dropping funnel under a nitrogen stream. After completion of the dropwise addition, the mixture was stirred for 2 hours at 75° C., then for 2 hours at 90° C. Thus, fluorine-containing polymer (C-1) was obtained.

It was found that that the polymer had a weight average molecular weight of 35,000 by the GPC measurement.

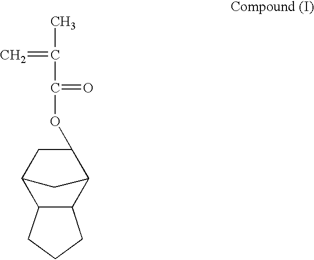

Synthesis of Fluorine-Containing Polymer D-1

26.4 g of fluorine-containing monomer (M-22) described hereinbefore, 25.6 g of compound (II) shown below, 20.4 g of lauryl methacrylate and 160 g of dimethylacetmide were placed in a 500-ml 3-necked flask, and the mixture was kept at 65° C. with stirring under a nitrogen stream. 2.30 g of 2,2-azobis(2,4-dimethylvaleronitrile) was added thereto, and the stirring was continued. After 4 hours, the temperature was raised up to 75° C., and kept at the level for 1 hour. After completion of the reaction, the reaction mixture was cooled to room temperature, and was poured into 400 ml of water. The solid thus precipitated was filtered out and dried. Thus, fluorine-containing polymer (D-1) having the structure shown below was obtained in a yield of 68.4 g.

It was found that that the polymer had a weight average molecular weight of 40,000 by the GPC measurement.

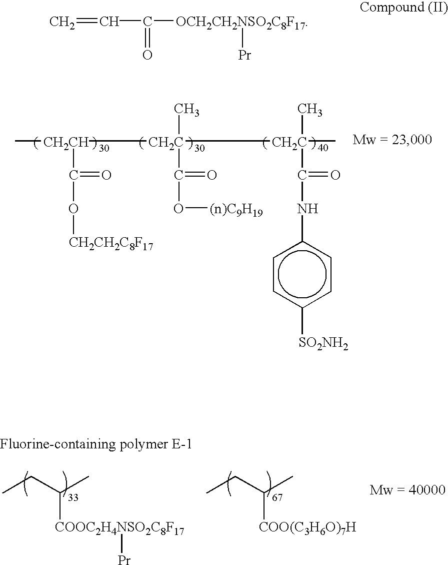

<Synthesis of Specific Copolymer 1>

31.0 g (0.36 mol) of methacrylic acid, 39.1 g (0.36 mol) of ethyl chloroformate and 200 ml of acetonitrile were placed in a 500-ml 3-necked flask equipped with a stirrer, a condenser and a dropping funnel, and the mixture was stirred while cooling in an ice-water bath. To the mixture was dropwise added 36.4 g (0.36 mol) of triethylamine over a period of about 1 hour through the dropping funnel. After completion of the dropwise addition, the ice-water bath was removed, and the mixture was stirred for 30 minutes at room temperature.

51.7 g (0.30 mol) of p-aminobenzenesulfonamide was added to the reaction mixture, followed by stirring for 1 hour under heating at 70° C. in an oil bath. After completion of the reaction, the mixture was poured into 1 liter of water while stirring the water, followed by stirring the resulting mixture for 30 minutes. The precipitate thus formed was collected by filtering the mixture, and was made into a slurry using 500 ml of water. Then, the slurry was filtered, and the solid thus obtained was dried to obtain a white solid of N-(p-aminosulfonylphenyl)methacrylamide. (Yield: 46.9 g)

Next, 4.61 g (0.0192 mol) of N-(p-aminosulfonylphenyl)methacrylamide, 2.94 g (0.0258 mol) of ethyl methacrylate, 0.80 g (0.015 mol) of acrylonitrile and 20 g of N,N-dimethylacetamide were placed in a 20-ml 3-necked flask equipped with a stirrer, a condenser and a dropping funnel, and the mixture was stirred under heating at 65° C. in a hot water bath. To the mixture was added 0.15 g of V-65 (made by Wako Pure Chemical industries, Ltd.), and the mixture was stirred for 2 hours in a nitrogen stream while keeping the temperature at 65° C. To the reaction mixture was further dropwise added a mixture of 4.61 g of N-(p-aminosulfonylphenyl)methacrylamide, 2.94 g of ethyl methacrylate, 0.80 g of acrylonitrile, 14.4 g of N,N-dimethylacetamide and 0.15 g of V-65 over a period of 2 hours through the dropping funnel. After completion of the dropwise addition, the resulting mixture was further stirred at 65° C. for 2 hours. After completion of the reaction, 40 g of methanol was added to the mixture, and the mixture was cooled. The mixture was poured into 2 liter of water under stirring the water and, after stirring the mixture for 30 minutes, the precipitate formed was collected by filtration and dried to obtain 15 g of a white solid.

It was found that that specific copolymer 1 had a weight average molecular weight (in terms of standard polystyrene) of 53,000 by the GPC measurement.

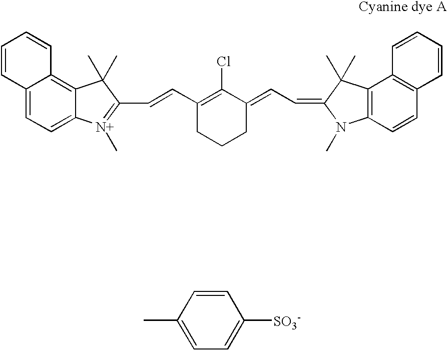

Additive B

S(C₂H₄COOC₁₄H₂₉)₂

Additive C

S(C₂H₄COOC₁₂H₂₅)₂

### EXAMPLES 1 TO 3 AND COMPARATIVE EXAMPLE 1

Each of the thus-prepared lithographic printing plate precursors was exposed at a main scanning speed of 5 m/sec using a semiconductor laser of 500 mW in output, 830 nm in wavelength and 17 μm (1/e²) in beam diameter, then subjected to development processing using an automatic developing processor LP940H made by Fuji Photo Film Co., Ltd. In this occasion, developing solution DT-1 (1:8) made by Fuji Photo Film Co., Ltd. was charged in the developing tank, and each of finishing solutions different from each other in pH as shown in Table 1 below was charged in the finishing tank.

Evaluation was conducted by counting the number of scum deposited on the surface of lithographic printing plate precursor (1030 mm×800 mm) processed by the automatically development processor.

TABLE 1

| | | PH of | Scum Deposited |
|---|---|---|---|
| | | Finishing | on Plate Surface |
| | Finishing Solution | Solution | (number/sheet) |
| Example 1 | FP-2W(1:1) whose pH was | 4.5 | 0 |
| | adjusted with NaOH | | |
| Example 2 | FP-2W(1:1) whose pH was | 6.0 | 0 |
| | adjusted with NaOH | | |
| Example 3 | FP-2W(1:1) whose pH was | 7.0 | 0 |
| | adjusted with NaOH | | |
| Com. Ex. 1 | FP-2W (1:1) | 3.2 | 5 |

Note) FP-2W: Finishing solution made by Fuji Photo Film Co., Ltd.
(1:1): dilution ratio with water

It is seen from Table 1 that the deposition of development scum on the plate surface occurred in the processing by automatic development processor can be prevented by adjusting pH of the finishing solution at the feed to 4.5 or more.

According to the invention, the deposition of scum on the surface of non-image areas of printing plate after the development processing can be prevented even when an infrared laser positive-working lithographic printing plate material is processed in an automatic developing processor.

The entire disclosure of each and every foreign patent application from which the benefit of foreign priority has been claimed in the present application is incorporated herein by reference, as if fully set forth herein.

While the invention has been described in detail and with reference to specific embodiments thereof, it will be apparent to one skilled in the art that various changes and modifications can be made therein without departing from the spirit and scope thereof.

What is claimed is:

1. A method for making a lithographic printing plate comprising development processing a laser beam exposed positive-working lithographic printing plate precursor comprising an aluminum support having thereon a heat-sensitive layer which contains a water-insoluble and alkali-soluble resin and an infrared absorbing agent and increases solubility in an alkaline aqueous solution upon being heated, using an automatic developing processor having a developing tank and a finishing gum-coating tank, wherein pH of a fresh solution for the finishing gum is adjusted to 4.5 or more.

2. The method for making a lithographic printing plate as claimed in claim 1, wherein the alkali-soluble resin comprises a copolymer containing a monomer having a sulfonamido group wherein at least one hydrogen atom is bonded to the nitrogen atom in an amount of 10 mol % or more as a copolymerizable component and an alkali-soluble resin having a phenolic hydroxyl group.
